(19) United States
(12) Patent Application Publication
(10) Pub. No.: US 2022/0325402 A1
(43) Pub. Date: Oct. 13, 2022

(54) THERMAL EVAPORATION PLASMA DEPOSITION

(71) Applicant: Dyson Technology Limited, Wiltshire (GB)

(72) Inventor: Michael Edward RENDALL, Newbury (GB)

(73) Assignee: Dyson Technology Limited, Wiltshire (GB)

(21) Appl. No.: 17/638,796

(22) PCT Filed: Aug. 21, 2020
(86) PCT No.: PCT/GB2020/052019

§ 371 Date: Feb. 25, 2022

(30) Foreign Application Priority Data
Aug. 30, 2019 (GB) 1912495.7

(51) Int. Cl. C23C 14/32; C23C 14/24; H01M 4/04

(52) U.S. Cl. CPC C23C 14/32; C23C 14/243; H01M 4/0423; H05H 1/4652

(57) ABSTRACT

A deposition system includes comprising an induction crucible apparatus configured to produce a material vapour. When in use, the induction crucible apparatus is configured to inductively heat a crucible to generate two or more thermal zones in the crucible. The deposition system further includes a substrate support configured to support a substrate and a plasma source configured to generate a plasma between the induction crucible apparatus and the substrate support such that transmission of the material vapour at least partly through the plasma generates a deposition material for deposition on the substrate.

### CROSS-REFERENCE TO RELATED APPLICATIONS

This application is the National Stage of International Application No. PCT/GB2020/052019 filed Aug. 21, 2020, and claims benefit of United Kingdom Application No. 1912495.7 filed Aug. 30, 2019, each of which are herein incorporated by reference in their entirety.

### TECHNICAL FIELD

The present invention relates to methods and apparatus for generating a deposition material to deposit on a substrate.

### BACKGROUND

Deposition is a process by which a material is deposited on a substrate. An example of deposition is thin film deposition in which a thin layer (typically from around a nanometre or even a fraction of a nanometre up to several micrometres or even tens of micrometres) is deposited on a substrate, such as a silicon wafer or web. An example technique for thin film deposition is Physical Vapour Deposition (PVD), in which material is vaporised to produce a material vapour, which is then deposited onto the substrate. An example of PVD is evaporative deposition, in which a material is heated in a vacuum in order to evaporate the material as a material vapour. Evaporation of the material vapour may not produce a constant material vapour e.g. there may be localised regions in the material vapour of higher or lower density. It may therefore be desirable to produce a constant material vapour in an efficient manner, for deposition on the substrate.

Another example of PVD is sputter deposition, in which material particles are ejected or sputtered from a surface of a material as a result of bombardment by energetic particles, such as ions. In examples of sputter deposition, a sputter gas, such as an inert gas, e.g. argon, is introduced into a vacuum chamber at low pressure, and the sputter gas is ionised using energetic electrons to create a plasma. Bombardment of the material by ions of the plasma ejects material vapour, which may then be deposited on the substrate. The deposition rate of the material vapour on the substrate may be lower than in other deposition processes, such as evaporative deposition. Furthermore, sputter deposition may not be suitable for depositing a large area of deposition material on the substrate with a uniform thickness, due to the finite size of the surface of the material that is bombarded by the ions. It may therefore be desirable to produce a constant material vapour for deposition on a large substrate area in an efficient manner

### SUMMARY

According to a first aspect of the present invention, there is provided a deposition system comprising an induction crucible apparatus configured to produce a material vapour. When in use, the induction crucible apparatus is configured to inductively heat a crucible to generate two or more thermal zones in the crucible. The deposition system further comprises a substrate support configured to support a substrate and a plasma source configured to generate a plasma between the induction crucible apparatus and the substrate support such that transmission of the material vapour at least partly through the plasma generates a deposition material for deposition on the substrate. By combining the induction crucible apparatus with the plasma source, a high rate of production of the material vapour can be combined with the ability to modify the material vapour to have a uniform or homogeneous density. As a result, a high rate of deposition material with a uniform density may be generated for deposition on the substrate. The high rate of production of the material vapour may be achieved using a relatively lower energy for the deposition system, compared to electron-beam deposition or resistive heating of a crucible. As such, a lower energy is required to evaporate the material in the crucible to create a material vapour. Furthermore, use of the induction crucible apparatus may allow for a high degree of control of the stoichiometry of the deposition material due to the ability to control the evaporation (or vaporisation) rate of the material in the crucible to create the material vapour, compared to electron-beam deposition or plasma vapour deposition.

The induction crucible apparatus may comprise the crucible and one or more induction coils arranged around the crucible such that, upon application of electric power to the one or more induction coils, a first thermal zone is generated in at least a first portion of the crucible and a second thermal zone is generated in at least a second portion of the crucible. A first temperature of the first thermal zone may be different from a second temperature of the second thermal zone. Generating a first thermal zone and a second thermal zone in the crucible with different temperatures may provide the ability to independently control the thermal zones in the crucible. Independently controlling the thermal zones may allow one zone, for example the second thermal zone, to be configured at a higher temperature. The induction crucible apparatus may, in some examples, provide a simple and efficient apparatus for allowing a material in the crucible to be held at over 2000 degrees C., without the need for further heating systems e.g. an electron-gun system. Such a configuration may provide an efficient way of generating a high-pressure vapour flux of the material in the crucible.

The one or more induction coils may comprise a first induction coil arranged around the first portion of the crucible and a second induction coil arranged around the second portion of the crucible. A first electric power may be applied to the first induction coil and a second electric power, different from the first electric power, may be applied to the second induction coil. Application of different electric powers to the first and second induction coils allows the first and second thermal zones in the crucible to have different thermal temperatures. Independently controlling the electric powers applied to the induction coils, and therefore independently controlling the temperature of the thermal zones, may allow for a greater control of the heating of the material in the crucible.

The first portion of the crucible may be located between a base of the crucible and the second portion of the crucible. Upon application of electric power to the one or more induction coils, the first temperature of the first thermal zone may meet or exceed a first temperature threshold for melting of the material to be heated by the induction crucible apparatus. Additionally, or alternatively, upon application of electric power to the one or more induction coils, the second temperature of the second thermal zone may meet or exceed a second temperature threshold for vaporisation of the material to be heated by the induction crucible apparatus to produce the material vapour. Configuring a lower temperature in the first thermal zone below a higher temperature in the second thermal zone may minimise spits and splashes of the material contained within the crucible. This is due to the fact that the material in the first thermal zone is heated at a lower rate than the material in the second thermal zone.

The plasma source may be configured to generate the plasma between the induction crucible apparatus and the substrate support such that the plasma is substantially absent from the crucible. Generating the plasma such that it is substantially absent from the induction crucible apparatus may reduce damage to the crucible by the plasma.

The deposition system may comprise a gas supply system configured to provide at least one gas between the induction crucible apparatus and the substrate support. Reactions between the material vapour and the gas may provide the ability to perform a reactive deposition process. The gas may comprise one or more chemical elements and/or molecules that may chemically react with the material vapour, yielding one or more deposition materials. Furthermore, the material vapour may be or comprise a precursor material so that a reaction with the gas may generate a deposition material. The ability to perform a reactive deposition process provides the possibility of generating a wide variety of deposition material for deposition on the substrate.

The gas supply system may comprise at least one of a first gas inlet to provide a first gas though the plasma, a second gas inlet to provide a second gas between the plasma and the induction crucible apparatus, or a third gas inlet to provide a third gas between the plasma and the substrate support. Transmission of the material vapour through the first gas, second gas and/or third gas may cause the material vapour to interact with the gas. Such interactions may generate, at least in part, a deposition material. As mentioned above, interactions with the gas may form part of a reactive deposition process.

The gas supply system may be configured to control a rate at which the at least one gas is provided between the induction crucible apparatus and the substrate support. Controlling the rate at which the at least one gas is provided may provide the ability to control properties of the generated deposition material. As a result, the deposited material on the substrate may have properties or characteristics which are determined by the rate at which the gas is provided to the deposition system.

The deposition system may be configured to transmit the material vapour at least partly through the plasma and/or at least partly through the gas. The material of the material vapour may interact with the at least one gas and/or the plasma to generate the deposition material. The material vapour may interact with the plasma to modify properties of the material vapour, in order to generate the deposition material. Properties of the material vapour may be considered to be physical or material properties (such as the thermal energy or density of the material vapour) and/or chemical properties (such as the chemical composition).

The deposition system is arranged for use in manufacture of an energy storage device. The manufacture of energy storage devices may involve the deposition of relatively thick layers or films instead of thin films. To deposit thick films, a deposition system which has a high degree of reproducibility and control is desirable, such as the deposition system of the present invention.

In accordance with a second aspect of the present invention, there is provided a method for depositing a deposition material on a substrate. The method comprises inductively heating an induction crucible apparatus to generate two or more thermal zones to heat material contained in the induction crucible apparatus to produce a material vapour. The method further comprises generating a plasma between the induction crucible apparatus and the substrate. The method further comprises transmitting the material vapour at least partly through the plasma to generate the deposition material and depositing the deposition material on the substrate. By combining the induction crucible apparatus with the plasma, a high rate of production of the material vapour can be combined with the ability to modify the material vapour to have a uniform or homogeneous density. As a result, a high rate of deposition material with a uniform density may be generated for deposition on the substrate.

Inductively heating the induction crucible apparatus may comprise applying electric power to one or more induction coils arranged around a crucible of the induction crucible apparatus to generate a first thermal zone in a first portion of the crucible and a second thermal zone in a second portion of the crucible. A first temperature of the first thermal zone may be different from a second temperature of the second thermal zone. Application of different electric powers to the first and second induction coils allows the first and second thermal zones in the crucible to have different temperatures. Independently controlling the electric powers applied to the induction coils, and therefore independently controlling the temperature of the thermal zones, may allow for a greater control of the heating of the material in the crucible. Heating the material within the crucible may allow the material to be evaporated to create a material vapour.

The first portion of the crucible may be located between a base of the crucible and the second portion of the crucible. Inductively heating the induction crucible apparatus may further comprise configuring the first temperature and the second temperature to melt a first portion of the material in the first portion of the crucible and/or vaporise a second portion of the material in the second portion of the crucible to produce the material vapour. Melting the first portion of the material and vaporising the second portion of the material may minimise spits and splashes of the material. This is due to the fact that the first portion of material is heated at a lower rate than the second portion of the material.

The plasma may be substantially absent from the induction crucible apparatus. Configuring the plasma to be substantially absent from the induction crucible apparatus may reduce damage to the crucible by the plasma.

At least one gas may be provided between the induction crucible apparatus and the substrate. Reactions between the material vapour and the gas may provide the ability to perform a reactive deposition process. The gas may comprise one or more chemical elements and/or molecules that may chemically react with the material vapour, yielding one or more deposition materials. Furthermore, the material vapour may be or comprise a precursor material so that a reaction with the gas may generate a deposition material. The ability to perform a reactive deposition process provides the possibility of generating a wide variety of deposition material for deposition on the substrate.

Generating the deposition material may comprise material of the material vapour interacting with the at least one gas and/or the plasma. The material of the material vapour may interact with the at least one gas and/or the plasma to generate the deposition material. The material of the material vapour may interact with the gas and/or the plasma to modify properties of the material vapour, in order to generate the deposition material. Properties of the material vapour may be considered to be physical or material properties (such as the thermal energy or density of the material vapour) and/or chemical properties (such as the chemical composition). Due to transmission through the plasma, the deposition material may comprise an energetic cloud of ions, electrons and neutral atoms/molecules, which may undergo further interactions with the gas to generate the deposition material. As such, the deposition material may comprise a high-energy deposition material which avoids the need for an additional step in the deposition process (e.g. an annealing step) to provide more energy to the deposition material when deposited on the substrate.

A gas of the at least one gas may be provided at a first rate at a first time to generate the deposition material as a first deposition material at the first time. The first deposition material may be generated by transmission of the material vapour at least partly the plasma and at least partly through the gas. Furthermore, a gas of the at least one gas may be provided at a second rate, different from the first rate, at a second time different from the first time. A second deposition material, different from the first deposition material, may be generated at the second time, by transmission of the material vapour at least partly the plasma and at least partly through the gas. The first deposition material may have a different chemical composition than the second deposition material. Controlling the rate at which the at least one gas is provided may provide the ability to control properties of the generated deposition material, such as the chemical composition. As a result, the deposited material on the substrate may have properties or characteristics which are determined by the rate at which the gas is provided to the deposition system.

The at least one gas may comprise nitrogen, argon, oxygen, ammonia, nitrogen oxide and/or helium. Such gases may provide the ability to perform a reactive deposition process with the material vapour acting as a precursor material, in order to generate a deposition material.

A rate of providing a gas of the at least one gas may be controlled in order to control a crystallinity of the deposition material deposited on the substrate. Controlling the rate of providing gas (e.g. the concentration of the gas) may be used to control the rate of reaction between the gas and the material vapour, in order to control the crystal structure (e.g. crystallinity) of the deposition material that is generated from the reaction.

A rate of production of the material vapour and/or a density of the plasma may be controlled in order to control a material property of the deposition material. Controlling the rate of production of the material vapour may provide the ability to control the thickness and/or the density of the deposition material deposited on the substrate. Controlling the density of the plasma may provide the ability to control the uniformity or homogeneity of the deposition material deposited on the substrate.

Depositing the deposition material on the substrate may comprise depositing the deposition material substantially homogeneously on the substrate. Depositing a substantially homogeneous deposition material generates an even or uniform deposition material on the substrate.

The deposition material deposited on the substrate may comprise material for an electrode layer or an electrolyte layer of an energy storage device. The manufacture of energy storage devices may involve the deposition of relatively thick layers or films instead of thin films. To deposit thick films, a deposition process which has a high degree of reproducibility and control is desirable, such as the deposition process of the present invention.

Further features will become apparent from the following description, given by way of example only, which is made with reference to the accompanying drawings.

### BRIEF DESCRIPTION OF THE DRAWINGS

FIG. 1 is a schematic diagram of a deposition system according to examples;

FIG. 2 is a schematic diagram of an induction crucible apparatus according to examples;

FIG. 3 is a schematic diagram of an induction crucible apparatus according to further examples;

FIG. 4 is a schematic diagram of an induction crucible apparatus according to further examples;

FIG. 5a is a schematic diagram of a substrate support according to examples;

FIG. 5b is a schematic diagram of a substrate support according to further examples;

FIG. 6 is a schematic diagram of a plasma source according to examples;

FIG. 7 is a schematic diagram of a plasma source according to further examples;

FIG. 8 is a schematic diagram of a deposition system according to further examples; and

FIG. 9 is a flow diagram illustrating a method for depositing a deposition material on a substrate.

### DETAILED DESCRIPTION

Details of methods and systems according to examples will become apparent from the following description, with reference to the Figures. In this description, for the purpose of explanation, numerous specific details of certain examples are set forth. Reference in the specification to “an example” or similar language means that a particular feature, structure, or characteristic described in connection with the example is included in at least that one example, but not necessarily in other examples. It should further be noted that certain examples are described schematically with certain features omitted and/or necessarily simplified for ease of explanation and understanding of the concepts underlying the examples.

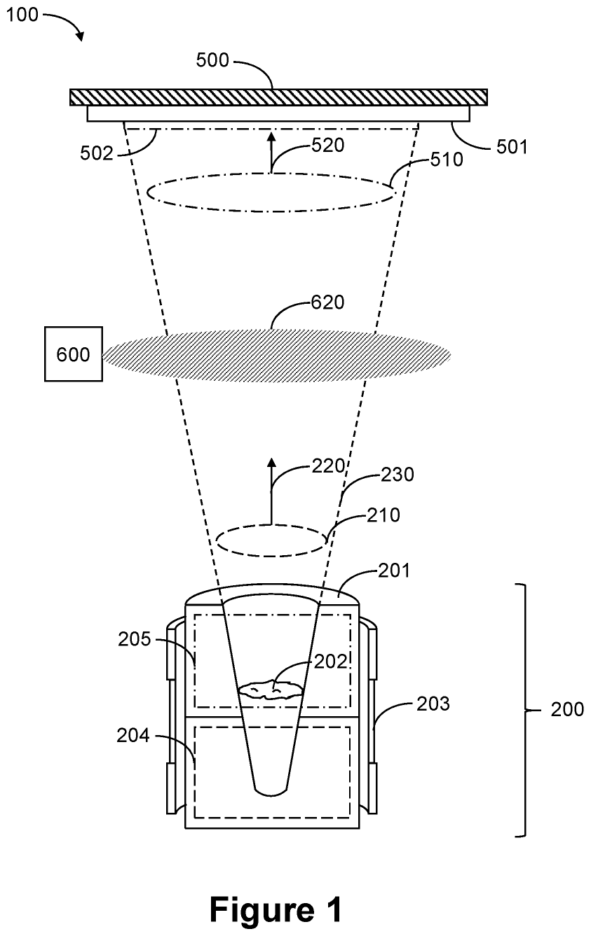

FIG. 1 is a schematic diagram of a deposition system 100. The deposition system 100 in this example comprises an induction crucible apparatus 200, a substrate support 500 and a plasma source 600.

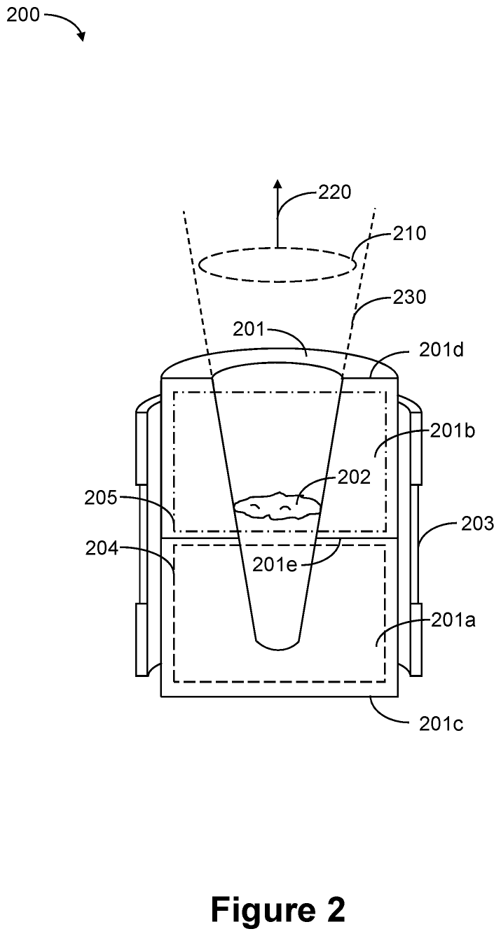

The induction crucible apparatus 200 is configured to produce a material vapour 210. The induction crucible apparatus 200 may inductively heat a crucible 201 to generate two or more thermal zones 204,205 in the crucible 201. The induction crucible apparatus 200 is described below with reference to FIGS. 2 to 4.

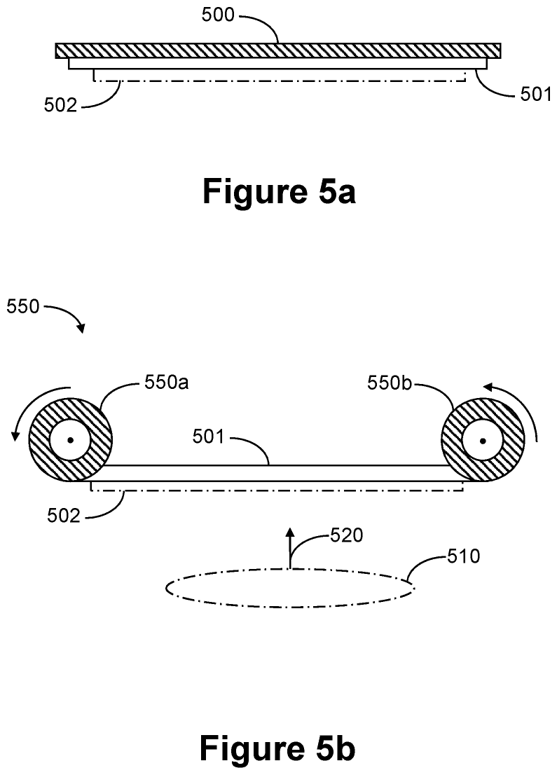

The substrate support 500 is configured to support a substrate 501. The substrate support 500 is described below with reference to FIGS. 5a and 5b.

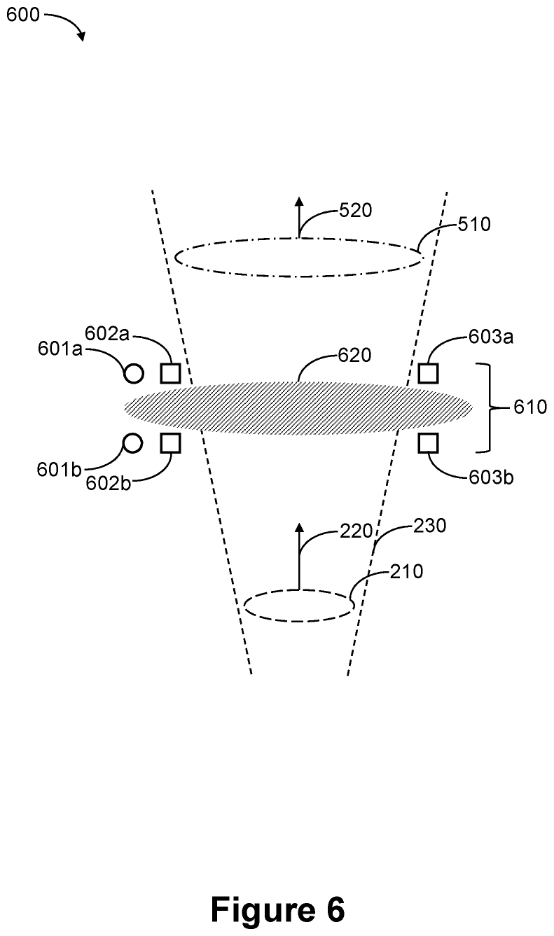

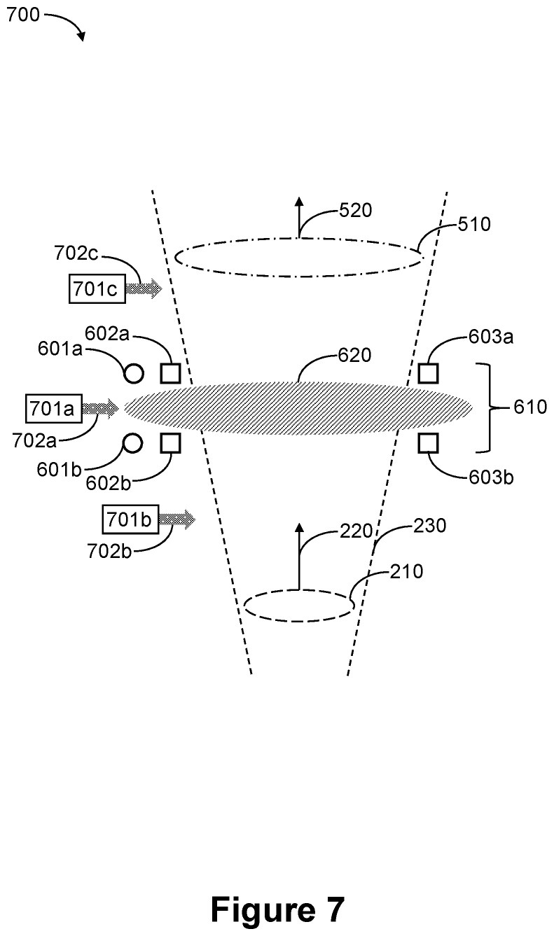

The plasma source 600 is configured to generate a plasma 620 between the induction crucible apparatus 200 and the substrate support 500. The transmission of the material vapour 210, at least partly through the plasma 620, generates a deposition material 510 for deposition on the substrate 501. The plasma source 600 is described below with reference to FIGS. 6 and 7.

Although not shown in the Figures for clarity, it is to be appreciated that the deposition system 100 may be located within a deposition chamber. When in use, the deposition chamber may be evacuated to a low pressure suitable for a deposition process, for example 3×10⁻³ torr. For example, the deposition chamber may be evacuated by a vacuum pump system to a suitable pressure (for example less than 1×10⁻⁵ torr). When in use, a gas, such as argon or nitrogen, may be introduced into the deposition chamber using a gas supply system to an extent such that a pressure suitable for the deposition process is achieved.

The material vapour 210 produced by the induction apparatus source 200 may travel in a direction 220 towards the substrate 501. The region in which the material vapour may be present may be referred to as a deposition zone 230. The deposition zone 230 comprises a region between the induction crucible apparatus 200 and the substrate support 500 where the material vapour 210 may travel. The edges of the deposition zone 230 are illustrated by dashed lines originating from the induction crucible apparatus 200 and finishing at the substrate support 500.

FIG. 2 is a schematic diagram of an induction crucible apparatus 200. The features of FIG. 2 which are similar to corresponding features of FIG. 1 are labelled with the same reference numeral. Corresponding descriptions are to be taken to apply, unless otherwise stated.

The induction crucible apparatus 200 in this example comprises a crucible 201 and one or more induction coils 203 arranged around the crucible 201. A crucible is, for example, a vessel or container for a containing a material to be thermally heated. Material within the crucible may be heated to a temperature such that the material is melted e.g. changed into a liquid state. The crucible may be manufactured from a heat-resistant material, such as, but not limited to, graphite, porcelain, ceramic, alumina or metal. The heat-resistant material of the crucible may be chosen in order to withstand the temperature required to melt the material within the crucible. The material and dimensions (e.g. the size and/or shape) of a crucible can be chosen based on requirements of use of the crucible.

The crucible 201 may be used to heat material 202 within the crucible 201 using the one or more induction coils 203. Heating the material 202 causes a rise in temperature of the material due to an increase in thermal energy of the material 202. Heating of the material 202 may arise as a result of the application of electric power to one or more induction coils 203.

An induction coil 203 may comprise a continuous coil of wire, which may have a plurality of turns of wire. The wire may be manufactured from or comprise an electrically conductive material, for example copper. Such a wire is therefore capable of conducting an electrical current through the induction coil. The plurality of turns of wire may be configured as successive loops or circles of wire arranged around a central axis. In some examples, the plurality of turns of wire are arranged around a central axis in circles with ever increasing radii. In other examples, the plurality of turns of wire are arranged around a central axis in circles with the same radius, but such that the centre of the circles lie on a straight line. A single length of wire may be considered to be one induction coil, as explained above.

Electric power may be applied to the single induction coil. Two or more separate lengths of wire, which are for example electrically disconnected from each other, may be considered to be two or more single induction coils. Electric power may be applied to each induction coil independently e.g. with a first electric power applied to a first induction coil and a second electric power applied to a second induction coil. The presence of one or more induction coils 203 around the crucible 201 allows the material 202 in the crucible 201 to be heated via induction heating. By passing an alternating current (AC) through an induction coil, eddy currents may be induced within a material surrounded by the induction coil. An eddy current for example comprises one or more closed loops of electrical current that are induced within an electrical conductor due to the presence of an alternating magnetic field. A current can be passed through an induction coil to generate a magnetic field. Alternating the current passing through the induction coil will then alternate the magnetic field, which creates eddy currents.

The eddy currents generate thermal energy which heats up the material. For materials that are electrically conductive, this process heats up the material. Such electrically conductive materials may also be known as induction susceptors. For materials that have poor electrical conductivity, the crucible inside the coil may be manufactured out of or otherwise comprise an induction susceptor, such as graphite, which can then contain the poorly conductive material. Thus, the crucible may be inductively heated, and the material contained within the crucible may be conductively heated.

The induction crucible apparatus 200 may contain material 202 in the crucible 201 that is initially in a solid or liquid state. Upon heating the material 202 in the crucible 201 via induction heating, the material may change into a liquid state, which may be referred to as a molten state. Application of further heating may cause the molten material 202 to vaporise e.g. change into a gaseous state, also referred to as a material vapour 210, evaporating from the molten material 202. The material vapour 210 may be deposited on to a substrate to create a layer of deposited material. Additionally, or alternatively, the material vapour may be used in chemical reaction, as part of a reactive deposition process, before being deposited on to the substrate the create a layer of deposited material.

Deposition is a process by which material is provided on a substrate. A substrate on which a material may be deposited is for example glass or polymer and may be rigid or flexible and is typically planar. By depositing a stack of layers on a substrate, energy storage devices such as solid-state cells may be produced. The stack of layers typically includes a first electrode layer, a second electrode layer, and an electrolyte layer between the first electrode layer and the second electrode layer.

The first electrode layer may act as a positive current collector layer. In such examples, the first electrode layer may form a positive electrode layer (which may correspond with a cathode during discharge of a cell of the energy storage device including the stack). The first electrode layer may include a material which is suitable for storing lithium ions by virtue of stable chemical reactions, such as lithium cobalt oxide, lithium iron phosphate or alkali metal polysulphide salts.

In alternative examples, there may be a separate positive current collector layer, which may be located between the first electrode layer and the substrate. In these examples, the separate positive current collector layer may include nickel foil, but it is to be appreciated that any suitable metal could be used, such as aluminium, copper or steel, or a metalised material including metalised plastics such as aluminium on polyethylene terephthalate (PET).

The second electrode layer may act as a negative current collector layer. The second electrode layer in such cases may form a negative electrode layer (which may correspond with an anode during discharge of a cell of an energy storage device including the stack). The second electrode layer may include a lithium metal, graphite, silicon or indium tin oxide (ITO). As for the first electrode layer, in other examples, the stack may include a separate negative current collector layer, which may be on the second electrode layer, with the second electrode layer between the negative current collector layer and the substrate. In examples in which the negative current collector layer is a separate layer, the negative current collector layer may include nickel foil. It is to be appreciated, though, that any suitable metal could be used for the negative current collector layer, such as aluminium, copper or steel, or a metalised material including metalised plastics such as aluminium on polyethylene terephthalate (PET).

The first and second electrode layers are typically electrically conductive. Electric current may therefore flow through the first and second electrode layers due to the flow of ions or electrons through the first and second electrode layers.

The electrolyte layer may include any suitable material which is ionically conductive, but which is also an electric insulator, such as lithium phosphorous oxynitride (LiPON). As explained above, the electrolyte layer is for example a solid layer, and may be referred to as a fast ion conductor. A solid electrolyte layer may have structure which is intermediate between that of a liquid electrolyte, which for example lacks a regular structure and includes ions which may move freely, and that of a crystalline solid. A crystalline material for example has a regular structure, with an ordered arrangement of atoms, which may be arranged as a two-dimensional or three-dimensional lattice. Ions of a crystalline material are typically immobile and may therefore be unable to move freely throughout the material.

The stack may for example be manufactured by depositing the first electrode layer on the substrate. The electrolyte layer is subsequently deposited on the first electrode layer, and the second electrode layer is then deposited on the electrolyte layer. At least one layer of the stack may be deposited using the systems or methods described herein.

The material 202 provided in the crucible 201 can be chosen depending upon the layer to be deposited on the substrate. For example, a first material may initially be arranged or otherwise provided in the crucible 201. The first material may be an electrically conductive material such as lithium cobalt oxide, for example to deposited on a substrate to form a first electrode layer for an energy storage device. Upon deposition of the first material on the substrate to the desired thickness, the first material in the crucible 201 may be replaced with a second material. The second material may be an ionically conductive but an electrically insulating material, such as lithium phosphorous oxynitride (LiPON), for example to deposited on the first electrode layer to form an electrolyte layer for the energy storage device. Once the second material has been deposited on the substrate to the desired thickness, the second material in the crucible 201 may be replaced with a third material. The third material may also be an electrically conductive material such as lithium metal, for example to deposited on the electrolyte layer to form a second electrode layer for the energy storage device. Upon deposition of the third material on the substrate to the desired thickness, further processing may be performed on the stack of deposited layers to create the energy storage device.

Typically, the manufacture of energy storage devices such as solid-state cells, may involve the deposition of relatively thick layers or films (for example, of the order of micrometres, sometimes referred to as microns) instead of thin films (for example, of the order of nanometres). To deposit films with this thickness, a deposition source which has a high degree of reproducibility and control is desirable.

Referring back to the induction crucible apparatus 200 of FIG. 2, in this example, the crucible 201 comprises a first portion 201a and a second portion 201b. Upon application of electric power to the one or more induction coils 203, a first thermal zone 204 is generated in at least the first portion 201a of the crucible 201 and a second thermal zone 205 is generated in at least the second portion 201b of the crucible 201. The first thermal zone 204 may have a first temperature and the second thermal zone 205 may have a second temperature, such that the first temperature is different from the second temperature. For example, upon application of electric power to the one or more induction coils 203, the first thermal zone 204 may have a different temperature than the temperature of the second thermal zone 205

Although the first thermal zone 204 is shown as separate and distinct from the second thermal zone 205 in FIG. 2, it is to be understood that upon application of the electric power to the one or more induction coils 203 the first and second thermal zones 204, 205 in the crucible 201 may not be separate and distinct. The first and second thermal zones 204, 205 may not be limited to the areas illustrated by the dashed lines of FIG. 2.

Instead, the first and second thermal zones 204, 205 may be thought of as portions of the crucible 201 which have, on average, a given temperature. For example, on average within the first thermal zone 204, the first thermal zone 204 may have a first temperature Similarly, on average within the second thermal zone 205, the second thermal zone 205 may have a second temperature. The first temperature and the second temperature may or may not be the same. When the first temperature and the second temperature are the same, the first and second thermal zones 204, 205 may nevertheless have different thermal characteristics due to, for example, different thermal gradients, temperature distributions or temperature profiles.

In some examples, a thermal zone may be present in a portion of the crucible. The thermal zone may be considered to be present within the material of the portion of the crucible, such that the thermal zone is limited to where the crucible material is present. In other words, the thermal zone may not extend outside the crucible material. For example, a first thermal zone 204 may be considered to be limited to the material of the portion 201a of the crucible 201. In other examples, a thermal zone may be present in a portion of the crucible and may also extend outside the crucible material. The thermal zone may be considered to be present within the material of the portion of the crucible and within a portion of a cavity of the crucible. In other words, the thermal zone may extend outside the crucible material to encompass the cavity of the crucible which contains the material 202 to be heated.

The first thermal zone 204, corresponding to the first portion 201a of the crucible 120110, may be located between a base 201c of the crucible 201 and the second portion 201b of the crucible 201. The base 201c of the crucible 201 may be referred to as the bottom of the crucible 201. The first thermal zone 204 may be considered to be located in the bottom portion of the crucible 201. The second thermal zone 205, corresponding to the second portion 201b of the crucible 201, may be located between the first portion 201a of the crucible 201 and a top 201d of the crucible 201. The second thermal zone 205 may be considered to be located in the top portion of the crucible 201.

In some examples, the first portion 201a of the crucible 201 and the second portion 201b of the crucible 201 may comprise a portion of the crucible 201 that is common to both the first portion 201a and the second portion 201b. As such, the first thermal zone 204 and the second thermal zone 205 may contain a portion of the crucible 201 that is common to both the first thermal zone 204 and the second thermal zone 205. In other words, the first thermal zone 204 and the second thermal 205 may partially overlap within the crucible 210.

In some examples, the first and second portions 201a, 201b of the crucible 201 may have different physical characteristics that enable the generation of the first and second thermal zones 204, 205. An interface between the first portion 201a of the crucible 201 and the second portion 201b of the crucible 201 is illustrated in FIG. 2 by the interface line 201e. The first potion 201a of the crucible 201 may have different physical characteristics from the second portion 201b of the crucible, such that when passing across the interface line 201e of the crucible 201, the physical characteristics of the crucible 201 change.

In one example, the first portion 201a of the crucible 201 may have a different electrical resistivity than the second portion 201b of the crucible 201. For example, the second portion 201b may have a higher electrical resistivity than the first portion 201a. When a given electric power is applied to a single induction coil surrounding or otherwise arranged around both the first and second portions 201a, 201b of the crucible 201, the second portion 201b of the crucible 201 may heat up more than the first portion 201a of the crucible 201, due to the higher electrical resistivity of the second portion 201b. This may create a second thermal zone 205 with a higher temperature than the first thermal zone 204. As explained above, the single induction coil may be considered to be one induction coil. An induction coil may comprise a continuous coil of wire, which may have a plurality of turns of wire.

In other examples, the induction crucible apparatus 201 may comprise a crucible 201 with the same or similar physical characteristics throughout the crucible 201. In order to generate a first thermal zone 204 and a second thermal zone 205, two or more induction coils 203 may be used in such cases. A first induction coil may be used to generate a first thermal zone 204 and a second induction coil may be used to generate a second thermal zone 205. Upon application of a first electric power to the first induction coil and a second electric power to the second induction coil, where the first electric power is different from the second electric power, the first thermal zone may have different thermal properties from the second thermal zone. For example, by applying a higher electric power to the second induction coil than the first induction coil, a higher temperature may be generated in the second thermal zone compared to the first thermal zone.

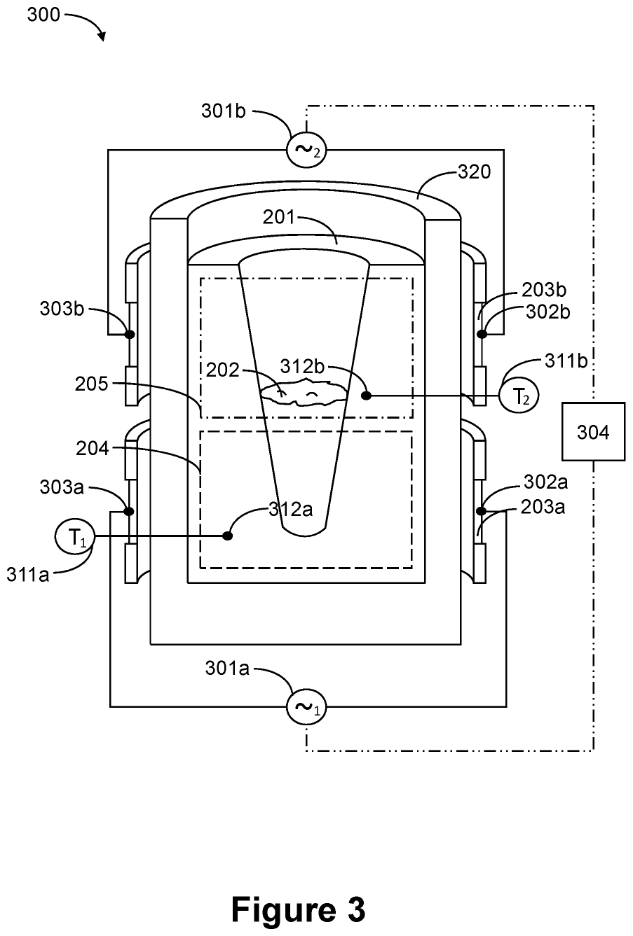

FIG. 3 is a schematic diagram of a generating a first thermal zone 204 and a second thermal zone 205 in an induction crucible apparatus 300. The features of FIG. 3 which are similar to corresponding features of FIGS. 1 and 2 are labelled with the same reference numeral. Corresponding descriptions are to be taken to apply, unless otherwise stated.

The induction crucible apparatus 300 comprises a first induction coil 203a and a second induction coil 203b. A first electric power source 301a may be configured to generate a first electric power, for example an AC power. The first electric power may be applied to the first induction coil 203a via one or more electric connections 302a, 303a. Arrangement of the first induction coil 203a around a portion of the crucible 201 generates a first thermal zone 204 in the crucible 201. A second electric power source 301b may be configured to generate a second electric power, for example an AC power. The second electric power may be applied to the second induction coil 201b via one or more electric connections 302b, 303b. Arrangement of the second induction coil 203b around a portion of the crucible 201 generates a second thermal zone 205 in the crucible 201.

An electric power source may also be referred to as a power supply. An electric power source is for example an electrical device or system that can supply electric power to an electrical load, in this case one or more induction coils. An electric power source typically converts electric current from the electric power source to a given voltage, current and frequency in order to power the induction coils.

An electric power source, such as the first electric power source 301a or the second electric power source 301b, may be controlled by a control system 304. The control system 304 is for example arranged to control the electric power applied to the one or more induction coils 203a, 203b. Such control may be based on input data received by the control system 304, such as measurement data (discussed further below). The control system may include a processor, which may be referred to as a controller and may be a microcontroller. The processor may be a central processing unit (CPU) for processing data and computer-readable instructions. The control system may also include storage for storing data and computer-readable instructions. The storage may include at least one of volatile memory, such as a Random Access Memory (RAM) and non-volatile memory, such as Read Only Memory (ROM), and/or other types of storage or memory. The storage may be an on-chip memory or buffer that may be accessed relatively rapidly by the processor. The storage may be communicatively coupled to the processor, e.g. by at least one bus, so that data can be transferred between the storage and the processor. In this way, computer-readable instructions for processing by the processor for controlling the induction crucible apparatus 300 and its various components in accordance with the examples described herein may be executed by the processor and stored in the storage. Alternatively, some or all of the computer-readable instructions may be embedded in hardware or firmware in addition to or instead of software. In some cases, the first and second induction coils 203a, 203b are arranged to receive electric power from the same power source, such as mains power, which may be referred to as a common power source. In such cases, the first and second power sources 301a, 301b may be omitted, and the control system 304 may instead receive electric power from the common power source and may control the first and second electric power supplied by the first and second induction coils 203a, 203b, respectively, to be different from one another. In yet further cases, there may be a first control system arranged to control the first electric power supplied by the first power source 301a and a second control system arranged to control the second electric power supplied by the second power source 301b such that the first electric power is different from the second electric power. In such cases, the first and/or second control system may be similar to the control system 304.

Electric power may be applied to one or more induction coils 203a, 203b by applying, for example, an AC power, e.g. using at least one power source. Control of the electric power may be provided through the control of the current, voltage and/or frequency of the AC power, for example using the control system 304. In some examples, the induction crucible apparatus 300 may operate at a pre-determined voltage and current. The pre-determined voltage and current may be selected to prevent the formation of plasma in the immediate vicinity of the induction crucible apparatus 300 and ablation of the material 202 in the crucible 201 when the induction crucible apparatus 300 is surrounded by a poor or medium vacuum.

In some examples, the first electric power 301a applied to the first induction coil 203a may be higher than the second electric power 301b applied to the second induction coil 203b. Application of a higher electric power will cause greater induction heating and a resulting higher temperature. As such, the first thermal zone 204, which corresponds to the first induction coil 203a, has a higher temperature than the second thermal zone 205 which corresponds to the second induction coil 203b in these examples.

In other examples, the second electric power 301b applied to the second induction coil 203b may be higher than the first electric power 301a applied to the first induction coil 203b. Application of a higher electric power will cause greater induction heating and a resulting higher temperature. As such, the second thermal zone 205, which corresponds to the second induction coil 203b, has a higher temperature than the first thermal zone 204 which corresponds to the second induction coil 203a in these examples.

When the first thermal zone 204 is at a lower temperature and the second thermal zone 205 is at a higher temperature, the material 202 contained within the crucible 201 may be melted in the first thermal zone 204 and vaporised in the second thermal zone 205. In some examples, the control system 304 may be arranged to control the electric power applied to the one or more induction coils 203a, 203b such that the first temperature meets or exceeds a first temperature threshold for melting the material 202 contained within the crucible 201. In some examples, the control system 304 may be arranged to control the electric power applied to the one or more induction coils 203a, 203b such that the second temperature meets or exceeds a second temperature threshold for evaporation of the material 202 contained within the crucible 201.

As shown in FIG. 3, the first thermal zone may contain some or a majority of the material 202 contained within the crucible 201. The second thermal zone 205 may contain some or a minority of the material 202 contained within the crucible 201. In such a scenario, a majority of the material 202 may be held at a temperature that causes the material 202 to be in a molten state and a minority of the material may be held at a temperature that causes the material 202 to be vaporised.

Configuring a lower temperature first thermal zone 204 below a higher temperature second thermal zone 205 may minimise spits and splashes of the molten material 202 in the crucible 201 as the material is heated and vaporised. This is due to the fact that the material 202 in the first thermal zone 204 is heated at a lower rate than the material 202 in the second thermal zone 205.

As mentioned above, in some examples the induction crucible apparatus 300 may be used as an evaporative deposition source. In such a scenario, the induction crucible apparatus 300 may operate at high temperatures, for example over 2000 degrees, in order to evaporate the material 202 to create a material vapour. High temperatures of over 2000 degrees may be achieved without the use of an electron-gun system to heat the material 202 in the crucible 201. The systems and methods herein may therefore be simpler than existing systems.

In such examples, the induction crucible apparatus 300 may be installed within a deposition chamber. The deposition chamber may contain a substrate on which a deposition material may be deposited. In some examples, the deposition material may be the material vapour generated from the induction crucible apparatus 300. In other examples, the deposition material may be created using the material vapour generated from the induction crucible apparatus 300.

Any gas (such as air, nitrogen, argon and/or any other inert or noble gas) present in the deposition chamber may be evacuated from the deposition chamber so that the vacuum pressure in the evacuated deposition chamber reaches a pre-determined vacuum pressure, for example 3×10−3 torr. Evacuation of the deposition chamber to a pre-determined pressure may be performed with use of a vacuum pump system. Such vacuum pump systems may comprise a scroll or rotary pump and/or a turbo pump to evacuate the gas and/or air within the deposition chamber.

When the induction crucible apparatus 300 is used as an evaporative deposition source, controlling the application of electric power to the one or more induction coils can be used to control the thermal characteristics of the first and second thermal zones 204, 205 in the crucible. As a result, the characteristics of the first and second thermal zones 204, 205 may determine the characteristics of the deposition of the deposition material on the substrate. For example, the ability to independently control the characteristics of the first and second thermal zones 204, 205 may provide control over the thickness and/or density of deposition of the deposition material on the substrate, the rate of deposition of the deposition material on the substrate (e.g. the vapour flux of the material vapour), the quality of the deposition (e.g. the uniformity of the vapour flux of the material vapour) etc. Tuning the electric power applied to one or more induction coils may provide the possibility of creating a high-pressure vapour flux of the material vapour for deposition on the substrate.

In some examples, the presence of two or more thermal zones 204, 205 may create one or more thermal gradients between the thermal zones. The creation of thermal gradients may cause motion of the molten material 202 in the crucible 201 e.g. to generate stirring of the molten material 202 in the crucible 201. The molten material 202 may be contained with a region of the first thermal zone 204 (which is generated in the first portion of the crucible 201) and a region of the second thermal zone 205 (which is generated in the second portion of the crucible 201). The regions of the first and second thermal zones 204, 205 may comprise some or all of the first and/or second thermal zones 204, 205. As such, stirring of the molten material 202 may be present between a region of the first thermal zone 204 and a region of the second thermal zone 205 due to a thermal gradient between the first thermal zone 204 and a second thermal zone 205.

Stirring of the molten material 202 may provide for a more uniform distribution of the thermal energy and thus ensure that there are no or fewer hot-spots or cold-spots in the material 202 contained in the crucible 201 when it is being heated e.g. so there is a relatively homogeneous distribution of the thermal energy. Induction heating of the material 202 may also generate induction stirring of the molten material 202. Induction stirring may also provide for a more homogeneous distribution of the thermal energy, and thus a more homogeneous molten material 202.

One or more temperature sensors may be coupled to the crucible 201 in order to measure thermal characteristics of the crucible 201. A first temperature sensor 311a may be coupled via a coupling mechanism 312a to the first thermal zone 204 of the crucible 201. Similarly, a second temperature sensor 311b may be coupled via a coupling mechanism 312b to the second thermal zone 205 of the crucible 201. The temperature sensors 311a, 311b may allow a temperature to be measured for at least one of the thermal zones 204, 205.

A coupling mechanism 312a, 312b may physically connect or couple the temperature sensor to a thermal zone 204, 205. In some examples, the temperature sensor 311a, 311b measures the temperature of the crucible itself within a given thermal zone 204, 205, as is shown in FIG. 2. For example, the temperature sensor 311a, 311b may be physically connected to the crucible itself e.g. on the outside of the crucible or within the material of the crucible. In other examples, the temperature sensor measures the temperature of the cavity of the crucible within a given thermal zone e.g. the temperature of the material contained within the crucible. For example, the temperature sensor may be physically connected to the cavity of the crucible or the material contained within the crucible.

The temperature sensors 311a, 311b may be any such device that measures the temperature of an object, such as a thermocouple, thermistor or a thermostat. The temperature sensors 311a, 311b may be arranged to be obtain measurement data representative of a measurement of at least one of a first or second temperature, respectively. In some examples, the first temperature is the temperature of the first thermal zone and the second temperature is the temperature of the second thermal zone.

In some examples, such as for the thermostat, measurement of the temperature of the first and/or second thermal zone 204, 205 may be used to control or partly control the electric power applied to an induction coil. The electric power applied to an induction coil may be controlled by a control system, such as the control system 304. The control system 304 may be arranged to control the electric power 301a, 301b based on received input data, which may comprise the measurement data obtained by the temperature sensors 311a, 311b.

For example, the electric power applied to the first and/or second induction coil 203a, 203b may be controlled by a feedback loop that is based, at least in part, on the temperature measurements by the temperature sensors 311a, 311b for the first and/or second thermal zones 204, 205. As a result, the temperature of the first and/or second thermal zones 204, 205 can be maintained automatically, without the need for manual intervention. As such, a substantially constant vapour flux of the material 202, or a vapour flux of the material 202 with fewer vapour flux variations than existing systems, in the second thermal zone 205 may be achieved. In other words, the vaporisation of the material 202 occurs at a substantially constant rate to produce a constant material vapour. The vapour flux of the material vapour may be considered to be substantially constant when the vapour flux is approximately constant. For example, the vapour flux of the material may be approximately constant within measurement tolerances or with a vapour flux variation of within plus or minus 1, 5 or 10 percent of the vapour flux.

The electric power applied to an induction coil may be controlled by a control system, such as the control system 304 in FIG. 3. For example, in response to input data indicative that a first temperature of the first thermal zone 204 is less than a first temperature threshold for melting of a material to be heated by the induction crucible apparatus 300, the control system 304 may control the first electric power 301a applied to the first induction coil 203a to increase the temperature within the first thermal zone 204 until the temperature within the first thermal zone 204 meets or exceeds the first temperature threshold. Similarly, in response to input data indicative that a second temperature of the second thermal zone 205 is less than a second temperature threshold for evaporation of the material, the control system 304 may control the second electric power 310b applied to the second induction coil 203b to increase the temperature within the second thermal zone 205 until the temperature within the second thermal zone 205 meets or exceeds the second temperature threshold. Conversely, the control system 304 may similarly be arranged to reduce the first and/or second electric power 301a, 301b if it is determined that the first and/or second temperature meets or exceeds a further first and/or second temperature threshold (e.g. corresponding to a flux of material evaporated from the crucible 201 which is too high for a desired use).

In some examples, insulation 320, such as expanded graphite insulation, may be arranged around the crucible 201 and between the crucible 201 and the one or more induction coils 203a, 203b. Insulation 320 is, for example, a heat-resistant material that can inhibit or otherwise limit the transfer of thermal energy. For example, the insulation 320 may inhibit the transfer of thermal energy from the crucible 201 to the induction coils 203a, 203b. By arranging the insulation 320 between the induction coils 203a, 203b and the crucible 201, the insulation 320 may protect the induction coils 203a, 203b from the heat from the crucible 201.

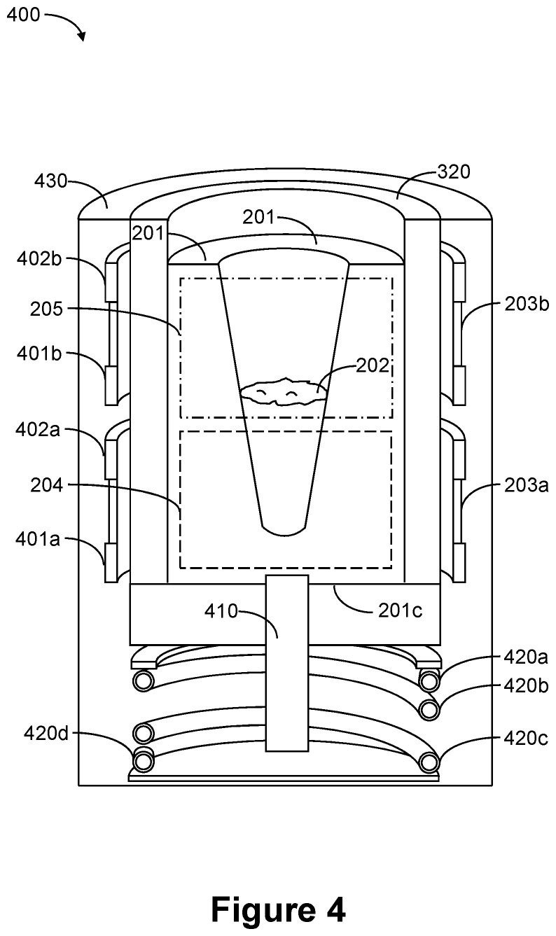

FIG. 4 is a schematic diagram of an induction crucible apparatus 400. The features of FIG. 4 which are similar to corresponding features of FIGS. 1 to 3 are labelled with the same reference numeral. Corresponding descriptions are to be taken to apply, unless otherwise stated.

The induction crucible apparatus 400, as explained above, may comprise a crucible 201 for containing material 202 to be heated via induction heating and one or more induction coils (in this case, a first and second induction coil 203a, 203b) that are arranged around the crucible 201. Between the crucible 201 and the first and second induction coils 203a, 203b, insulation 320 may be present in order to protect the first and second induction coils 203a, 203b from the heat generated within the crucible 201 upon application of electric power.

In some examples, at least one induction coil may be cooled by a cooling system. A first cooling system may be arranged to cool the first induction coil 203a. A second cooling system may be arranged to cool the second induction coil 203b. The first cooling system and the second cooling system may apply different amounts of cooling to the first induction coil 203a and the second induction coil 203b, respectively.

In some examples, at least one of the cooling systems is a water-cooling system. For example, at least one induction coil may be water-cooled by a water-cooling system. For example, the first induction coil 203a may be water-cooled by a first water-cooling system, which in this case includes first and second elements 401a and 402a (although this is merely an example). First and second elements 401a and 402a may comprise a tube, pipe or other such hollow container that allows water to flow through. The first and second elements 401a and 402a may be in thermal contact with the first induction coil 203a such that thermal energy may pass from the first induction coil 203a to the first and second elements 401a and 402a and to the water within. In FIG. 4, the first element 401a extends parallel to a lower edge of the first induction coil 203a and the second element 402a extends parallel to an upper edge of the first induction coil 203a, although this is merely an example Water flowing through the first and second elements 401a and 402a, around the first induction coil 203a, may heat up due to the thermal contact with the first induction coil 203a and transfer at least some of the thermal energy from the first induction coil away. As such, the water is used as a heat-transfer medium. The first and second elements 401a and 402a may be manufactured from copper, metal or other such thermally conductive material. Transferring the thermal energy away from the first induction coil 203a will cool the first induction coil 203a. The water in the first water-cooling system 401a, 402a may pass through the first element 401a and subsequently pass through the second element 402a in order to cool the first induction coil 203a.

Similarly, the second induction coil 203b may be water-cooled by a second water-cooling system, which in this example includes third and fourth elements 401b and 402b (although this is merely an example). The third and fourth elements 401b, 402b may be similar to the first and second elements 401a, 402a described above, but arranged to cool the second induction coil 203b rather than the first induction coil 203a.

The first water-cooling system 401a, 402a and the second water-cooling system 401b, 402b may be independent from each other or linked together. In one example, when the first water-cooling system 401a, 402a and the second water-cooling system 401b, 402b are independent, the water used in one water-cooling system is separate from the water used in the other system e.g. the systems run in parallel. In another example, when the first water-cooling system 401a, 402a and the second water-cooling system 401b, 402b are linked together, water is re-circulated from one water-cooling system to another e.g. the systems run in series.

The temperatures of the first and second thermal zones 204, 205 may be controlled by the configuration of the first water-cooling system 401a, 402a and the second water-cooling system 401b, 402b, respectively. For example, the electric power applied to the induction coils 203a, 203b may be substantially constant, which may result in a substantially similar inductive heating of the first and second thermal zones 204, 205. However, by application of different configurations of the first water-cooling system 401a, 402a and/or the second water-cooling system 401b, 402b, different cooling to the first and second thermal zones 204, 205 will arise. For example, if a greater water-cooling strength is applied to the first thermal zone 204 e.g. if the water that flows through the first water-cooling system 401a, 402a is configured to flow at a faster rate and thus remove more thermal energy from the first thermal zone 204, then a greater cooling will result for the first thermal zone 204. As a result, the first thermal zone 204 will have a lower temperature than the second thermal zone 205.

Although the water-cooling system has been described in relation to using water as the heat-transfer medium, it is to be noted that other coolants may be used. For example, other liquids with a high heat capacity may be used in the water-cooling systems, such as oil, deionised water or a solution of a suitable organic chemical e.g. ethylene glycol, diethylene glycol or propylene glycol.

A chamber 410, located below the crucible 201, may be installed in order to provide protection to the induction crucible apparatus 400 should the crucible 201 crack. The chamber 410 may be used to collect material 202 that escapes from the crucible 201, e.g. if the crucible 201 cracks. Collecting material 202 that leaks from the crucible 201 may prevent the material 202 from escaping into a deposition chamber and/or from contaminating other components nearby the induction crucible apparatus 400.

In addition, the chamber 410 may be water-cooled in order to prevent the transfer of thermal energy to the base 201c of the induction crucible apparatus 400. A third water-cooling system 420a-420d may be present to cool the base 201c of the induction crucible apparatus 400. The water for the water-cooling system 420a-420d may enter the water-cooling system at a first element 420a, pass through a second element 420b, pass through a third element 420c and may exit the water-cooling system at a fourth element 420d. As explained in relation to the first water-cooling system 401a, 402a and the second water-cooling system 401b, 402b, the first, second, third and fourth elements 420a, 420b, 420c and 420d may comprise a continuous tube, pipe or other such hollow container that allows water or another coolant to flow through.

In some examples, the induction coils 203a, 203b may be encased in a refractory material 430. The refractory material 430 may be arranged, at least in part, around the one or more induction coils 203a, 203b, for example. The first water-cooling system 401a, 402b and the second water-cooling system 401b, 402b may also be housed in the refractory material 430. A refractory material 430 is, for example, a heat-resistant material that can inhibit or otherwise limit the transfer of thermal energy. For example, the refractory material 430 may inhibit the transfer of thermal energy from the crucible 201 to the induction coils 203a, 203b. By encasing the induction coils 203a, 203b in the refractory material 430, the refractory material 430 may protect the induction coils 203a, 203b from damage from the heat from the crucible 201.

In some examples, the size and/or the shape of the induction crucible apparatus 400 may be configured in order to match the size and/or the shape of a substrate. For example, an induction crucible apparatus 400 may be manufactured or selected with particular dimensions in order to match the dimensions of the substrate. In other words, an appropriate crucible may be chosen for a given substrate. Matching the size and/or shape of the induction crucible apparatus 400 to the profile of the substrate may provide an efficient way to optimise the production of a material vapour for deposition of a deposition material on the substrate. For example, the material 202 in the crucible may be produced in such a geometry that the deposition material is deposited on all of the substrate, such that no portion of the substrate does not contain deposited material.

In some examples, the size and/or the shape of the induction crucible apparatus 400 may be configured in order to match a deposition chamber that contains the substrate. For example, an induction crucible apparatus may be manufactured or selected with particular dimensions in order to match the dimensions of the deposition chamber. In other words, an appropriate crucible may be chosen for a given deposition chamber. Matching the size and/or shape of the induction crucible apparatus 400 to the deposition chamber may also provide an efficient way to optimise the deposition of the material 420 in the crucible 410 on to the substrate in the deposition chamber. The induction crucible apparatus 400 may be selected based on a particular shape and/or dimension that matches the shape and/or dimension of the deposition chamber. Such selection may provide an efficient way to increase the size of the deposition of the deposition material on the substrate.

In some examples, the induction crucible apparatus 400 is installed within a deposition chamber. Due to the first and second thermal zones of the crucible 201 providing a material vapour, the deposition chamber may be maintained at higher vacuum pressures (i.e. lower vacuum) than an equivalent apparatus that comprises an electron-gun system to provide a material vapour. In such a scenario, maintaining the deposition chamber at a higher pressure may reduce the time for the air or gas in the deposition chamber to be evacuated, creating a more efficient process.

Maintaining the deposition chamber at higher pressures may provide the ability to perform reactive depositions during the deposition process. In reactive depositions, a gas in the deposition chamber, which may be injected into the deposition chamber, may comprise one or more chemical elements and/or molecules that may chemically react with the material vapour from the induction crucible apparatus 400. As a result, the material vapour and the elements and/or molecules may chemically react, yielding one or more deposition materials. The deposition material may then be used as part of the deposition process. For example, the deposition material may be deposited on a substrate.

In some examples, the induction crucible apparatus 400 may comprise a continuously fed system, whereby material is continuously fed or is fed more frequently than otherwise into the crucible 201, so that the amount of material 202 in the crucible 201 does not decrease or remains above a certain threshold amount. Inclusion of a continuously fed system in the induction crucible apparatus 400 may avoid the need to switch the induction crucible apparatus 400 off, in order to replenish the material 202 in the crucible 201. Such a scenario may decrease the amount of down-time of the induction crucible apparatus and provide a more efficient system.

FIG. 5a is a schematic diagram of a substrate support 500. The features of FIG. 5a which are similar to corresponding features of FIGS. 1 to 4 are labelled with the same reference numeral. Corresponding descriptions are to be taken to apply, unless otherwise stated. The substrate support 500 is configured to support a substrate 501. The substrate support 500 may be configured as a plate, wire, holder, roll-to-roll, reel-to-reel or other type of holding arrangement to support the substrate 501 in the deposition process. A deposition material may be deposited on to the substrate 501 to create a layer 502 of deposited material.

In some examples, the deposited material may comprise at least part of a material vapour produced by an induction crucible apparatus, such as the induction crucible apparatuses 200, 300, 400 described with reference to FIGS. 2 to 4. In some examples, the deposited material may comprise at least part of a result of a reactive deposition process. For example, a material vapour produced by an induction crucible apparatus may react with one or more gases in the deposition chamber. More specifically, the material vapour may react with one or more gases in a deposition zone. The one or more gases, which may be injected into the deposition chamber and enter in the deposition zone, may comprise one or more chemical elements and/or molecules that may chemically react with the material vapour from the induction crucible apparatus to form a deposition material. The deposition material may then be deposited on to the substrate to create a layer 502 of deposited material.

FIG. 5b is a schematic diagram of a substrate support 550. The features of FIG. 5b which are similar to corresponding features of FIGS. 1 to 4 are labelled with the same reference numeral. Corresponding descriptions are to be taken to apply, unless otherwise stated.

The substrate support 550 may comprise a substrate 501 that is supported by a support system 550a, 550b. The support system 550a, 550b may move the substrate 501 in one or more directions. A deposition material 510 may be deposited on to the substrate 501 to create a layer 502 of deposited material. The dot-dash outline of the layer 502 of the deposited material is illustrated as such to show that the layer 502 comprises the same deposited material as the deposition material 510. The deposition material 510 is deposited in a direction 520 onto the substrate 501 to create the layer 502 of deposited material.

The substrate support 550 may form part of a roll-to-roll or reel-to-reel system, as shown in FIG. 5b. The substrate support 550 may comprise one or more rollers 550a, 550b that assist in moving the substrate 501 relative to the deposition material 510. The substrate 501 may be supported by the rollers 550a, 550b.

The substrate 501 may be flexible, allowing it to be wound around the rollers 550a, 550bFor example, the substrate 501 may be first wound around a first roller 550a, gradually unwound from the first roller 550a in order for the deposition material 510 to be deposited on the substrate 501, and then the substrate 501 may be wound around a second roller 550b. This creates a continuous roll of substrate 501. In other examples, though, the substrate 501 may be relatively rigid or inflexible. In such cases, the substrate 501 may be moved relative to the deposition material 510 by the support system 550a, 550b without bending the substrate or without bending the substrate a substantial amount.

The roll of substrate 501 may have none, one or more layers 502 on the substrate 501 when it is wound around the roller 550a. In the example shown, there is a layer 502 of deposited material on the substrate 501. As the roll of substrate 501 is gradually unwound from the roller 550a, the substrate support moves the substrate 501 relative to the deposition material 510, that is travelling in the direction 520 towards the substrate 501.

FIG. 6 is a schematic diagram of a plasma generation system 600 comprising a plasma source 610. The features of FIG. 6 which are similar to corresponding features of FIGS. 1 to 5 are labelled with the same reference numeral. Corresponding descriptions are to be taken to apply, unless otherwise stated.

The plasma source 610 is configured to generate a plasma 620 between an induction crucible apparatus (not shown) and a substrate support (not shown). The plasma source 610 may be configured to generate the plasma 620 such that the plasma 620 is substantially absent from the induction crucible apparatus e.g. the plasma 620 is substantially absent from the crucible. The plasma 620 may be considered to be substantially absent when the plasma 620 is generated away from the induction crucible apparatus. For example, the plasma 620 may be generated so that the plasma 620 is not impinging or physically touching the induction crucible apparatus. There may be a space between the plasma 620 and the crucible, such that the plasma 620 generated by the plasma source 610 does not impinge or physically touch the material in the crucible.

As described above with reference to FIGS. 1 to 4, the induction crucible apparatus is configured to produce a material vapour 210. The region in which the material vapour may be present may be referred to as a deposition zone 230. The deposition zone 230 comprises a region between the induction crucible apparatus and the substrate support where the material vapour 210 may travel. The edges of the deposition zone 230 are illustrated by dashed lines.

The material vapour 210 may travel in a direction 220 away from the induction crucible apparatus and towards the plasma 620. Transmission of material vapour 210, at least partly through the plasma 620, may generate a deposition material 510 for deposition on a substrate. Due to transmission through the plasma 620, the deposition material 510 may comprise an energetic cloud of ions, electrons and neutral atoms/molecules.

In some examples, the material vapour 210 may interact with the plasma 620, modifying properties of the material vapour 210 to generate a deposition material 510. Properties of the material vapour 210 may be considered to be physical or material properties (such as the thermal energy or density of the material vapour) and/or chemical properties (such as the chemical composition). In some examples, interaction with the plasma 620 may cause the energy associated with the material vapour 210 to be retained or increased, in order to generate the deposition material 510. As such, the deposition material 510 may be deposited on the substrate with enough energy to form a deposited material with a high-energy crystalline structure. By interacting the material vapour 210 with the plasma 620 in order to provide more energy and thus generate a high-energy deposition material 510, the requirement to provide additional energy from an additional process step may be avoided. For example, the requirement of an annealing step in the deposition process may be avoided, as the interaction of the plasma 610 with the material vapour 210 may provide the required energy to generate the high-energy deposition material 510 needed to create a crystalline structure.

The plasma source 610 may be an inductively coupled plasma source, e.g. configured to generate an inductively coupled plasma 620. The plasma source 610 may comprise one or more antennae 601a, 601b e.g. through which appropriate radio frequency (RF) power may be driven by a radio frequency power supply system (not shown) to generate an inductively coupled plasma 620 from a gas in the deposition chamber. The plasma source 610 may be configured to generate the plasma 620, at least in part, in the deposition zone 230 of the deposition chamber. For example, the plasma 620 is generated in a location in the deposition chamber such that the material vapour 210, travelling in a direction 220 in the deposition zone 230, will be able to interact with the plasma 620.

In some examples, the plasma 620 may be generated by driving a radio frequency current through the one or more antennae 601a, 601b, for example at a frequency between 1 MHz and 1 GHz; a frequency between 1 MHz and 100 MHz; a frequency between 10 MHz and 40 MHz; or at a frequency of approximately 13.56 MHz or multiples thereof. The RF power causes ionisation of the gas in the deposition chamber to produce the plasma 620. Tuning the RF power driven through the one or more antennae 601a, 601b can affect the density of the plasma 620. Thus, by controlling the RF power at the plasma source 610, the characteristics of the plasma 620 may be controlled. This may in turn allow for improved flexibility in the operation of the deposition system 100.

The antennae 601a, 601b may be configured to generate the plasma 620 substantially away from the deposition zone 230 in the deposition chamber. The plasma 620 may be considered to be substantially away when the plasma 620 is generated outside the deposition zone 230 in the deposition chamber. For example, the plasma 620 may be generated, at least in part, outside the deposition zone 230. In other words, the plasma 620 may be generated remotely from the deposition zone 230. The plasma 620 may then be guided from outside the deposition zone 230 and confined within the deposition zone 230. The antennae 601a, 601b may extend substantially parallel to one another and may be configured laterally from one another. The antennae 601a, 601b may be considered to be substantially parallel to each other when the antennae 601a, 601b are arranged approximately parallel to each other. For example, the antenna 601a, 601b may be arranged parallel to each other within measurement tolerances or with an angular deviation of within plus or minus 1, 2 or 5 degrees from parallel. In other words, the distance between the antenna 601a, 601b is constant along the length of the antenna 601a, 601b. Furthermore, the antennae 601a, 601b may be configured laterally from one another, such that the antenna 601a, 601b are configured immediately above and below each other. For example, as shown in FIG. 6, antenna 601a is configured immediately above antenna 601b in the deposition chamber. Such a configuration of the antennae 601a, 601b may allow for a precise generation of an elongate region of plasma 620 between the antennae 601a, 601b, as the distance between the antennae 601a, 601b is consistent along the length of the antennae 601a, 601b. The plasma 620 may therefore be generated consistently along the length of the antennae 601a, 601b, creating an elongate region of plasma 620. The localised nature of the elongate region of plasma 620 may allow for precise confinement of the generated plasma 620 to the deposition zone 230.

In some examples, the antennae 601a, 601b may be configured such that the plasma 620 is generated across a region having a length corresponding to the width of the deposition zone 230. As such, the configuration may allow the plasma 620 to be available evenly or uniformly across the width of the deposition zone 230. This may allow for an even or uniform interaction of the material vapour 210 with the plasma 620, in order to generate an even or uniform deposition material 510 for deposition on the substrate.

Additionally, or alternatively, the antennae 601a, 601b may be similar in length to the width of the substrate supported by the substrate support. The antennae 601a, 601b may be configured such that the plasma 620 is generated across a region having a length corresponding to the width of the substrate. As such, the configuration may allow the plasma 620 to be available evenly or uniformly across the width of the substrate. This may allow for an even or uniform generation of the deposition material on the substrate, in order to deposit an even or uniform deposition material 510 on the substrate.

The plasma source 610 may comprise one or more confining elements 602a, 602b, 603a, 603a. The first confining element 602a, 602b may be configured between the antennae 601a, 601b and the deposition zone 230. The first confining element 602a, 602b may be arranged to guide the plasma 620 from the antennae 601a, 601b towards the deposition zone 230 and confine the plasma 620, at least partly, within the deposition zone 230, to allow the material vapour 210 to interact with the plasma 620.

The plasma 620 may, at least in the deposition zone 230, be a high-density plasma. For example, the plasma 620 may have, at least in the deposition zone 230, a density of 10¹¹ cm⁻³ or more. The high-density plasma 620 in the deposition zone 230 may allow for effective and/or high rate interaction between the material vapour 210 and the plasma 620.

The first confining element 602a, 602b may be a magnetic element configured to provide a first confining magnetic field to guide the plasma from antennae 601a, 601b towards the deposition zone 230 and confine the plasma, at least partly, within the deposition zone 230. The first confining magnetic field may be characterised by magnetic field lines arranged to follow a path from the antennae 601a, 601b towards the deposition zone 230. The plasma 620 tends to follow the magnetic field lines, and hence is confined by the first confining element 602a, 602b from the antennae 601a, 601b within the deposition zone 230. For example, ions of the plasma within the confining magnetic field and with some initial velocity will experience a Lorentz force that causes the ion to follow a periodic motion around the magnetic field line. If the initial motion is not strictly perpendicular to the magnetic field, the ion follows a helical path centred on the magnetic field line. The plasma containing such ions therefore tends to follow the magnetic field lines and hence is guided on a path defined thereby. Accordingly, the first confining element 602a, 602b may be suitably arranged so that the plasma 620 will be guided by the confining magnetic field towards the deposition zone 230 and confined, at least in part, within the deposition zone 230.

In some examples, the first confining element 602a, 602b may be arranged to provide a confining magnetic field characterised by magnetic field lines which, at least in the deposition zone 230, follow a path substantially parallel to that of the substrate support and/or the crucible apparatus. This may allow for more uniform distribution of plasma 620 across the deposition zone 230, which may in turn allow for a more uniform interaction between the material vapour 210 and the plasma 620 to generate the deposition material 510, and a more uniform deposition of the deposition material 510 on the substrate.

In some examples, as illustrated in FIG. 6, the plasma source 610 may comprise a first confining element 602a, 602b and a second confining element 603a, 603b. The plasma source 610 may be configured such that the deposition zone 230 is between a first confining element 602a, 602b and a second confining element 603a, 603b, so as to confine the plasma 620 within the deposition zone 230. For example, the first and second confining elements 602a, 602b, 603a, 603b may be magnetic elements. The first and second confining elements 602a, 602b, 603a, 603b may be arranged to provide together a confining magnetic field that confines the plasma 620 from the antennae 601a, 601b within to the deposition zone 230 (i.e. confines the plasma 620 between one side of the deposition zone 230 to the other). For example, the first and second confining elements 602a, 602b, 603a, 603b may be arranged such that a region of relatively high magnetic field strength is provided between first and second confining elements 602a, 602b, 603a, 603b. The region of relatively high magnetic field strength may extend through the deposition zone 230. The confining magnetic field produced by the first and second confining elements 602a, 602b, 603a, 603b may be characterised by magnetic field lines which, at least in the deposition zone 230, follow a path substantially parallel to that of the substrate support and/or the crucible apparatus. This may allow for more uniform distribution of plasma 620 across the deposition zone 230, which may in turn allow for a more uniform interaction between the material vapour 210 and the plasma 620 to generate the deposition material 510, and a more uniform deposition of the deposition material 510 on the substrate.

In some examples, at least one of the first and second confining elements 602a, 602b, 603a, 603b may be an electromagnet controllable to provide the confining magnetic field. For example, one or both of the first and second confining elements 602a, 602b, 603a, 603b may be an electromagnet. The plasma source 610 may comprise a controller (not shown) arranged to control a strength of the magnetic field provided by one or more of the electromagnets. This may allow for the confining magnetic field to be controlled, for example controlling the arrangement of the magnetic field lines that characterise the confining magnetic field. This may allow for adjustment of the plasma density between the induction crucible apparatus and the substrate support and hence for improved control over the deposition of the deposition material on the substrate. This may allow for improved flexibility in the operation of the deposition system.

In some examples, at least one of the first and second confining elements 602a, 602b, 603a, 603b may be arranged such that the plasma 620 is impinging or physically touching the material in the crucible. For example, the plasma 610 may be arranged to physically touch the surface or meniscus of the material in the crucible.

In some examples, at least one of the first and second confining elements 602a, 602b, 603a, 603b may be arranged such that the plasma 620 is substantially absent from the induction crucible apparatus. Such an arrangement may be configured to avoid the plasma 620 impinging or physically touching the material in the crucible. Furthermore, arranging the plasma 620 substantially away from the induction crucible apparatus reduces damage to the crucible by the plasma 620. For example, the plasma 620 may be arranged to be spaced away from the induction crucible apparatus at a distance of 1 millimetre to 1 metre or greater.

In some examples, at least one of the first and second confining elements 602a, 602b, 603a, 603b may be provided by a solenoid. Each solenoid may comprise one or more coils and may define an opening through or via which plasma 620 is confined or may otherwise pass, when in use.

As illustrated in FIG. 6, there may be first and second solenoidal confining elements 602a, 602b, 603a, 603b, between which the deposition zone 230 is located. The plasma 620 may pass, from the antennae 601a, 601b, through a first solenoidal confining element 602a, 602b, into the deposition zone 230, and towards and through the second solenoidal confining element 603a, 603b. The first solenoidal confining element 602a, 602b is illustrated in cross-section, showing two portions (e.g. 602a and 602b) of the first solenoidal confining element. Similarly, the second solenoidal confining element 603a, 603b is illustrated in cross-section, showing two portions (e.g. 603a and 603b) of the second solenoidal confining element 603a, 603b. The second solenoidal confining element 603a, 603b may have anyone or combination of features of the first solenoidal confining element 602a, 602b described above.

As described above, the material vapour 210 may be transmitted, at least partly, through the plasma 620. Transmission of the material vapour 210 through the plasma 620 may generate a deposition material 510 for deposition on a substrate.

In some examples, transmission of the material vapour 210 through the plasma 620 may allow the material vapour 210 to interact with the plasma 620. More specifically, the material vapour 210 may interact with the ionised gas of the plasma 620. Interaction of the material vapour 210 with the ionised gas of the plasma 620 may change or modify the properties of the material vapour 210, such that a deposition material 510 is generated. In other words, the material vapour 210 interacts with the plasma 620, changing the properties of the material vapour 210 in the process, to generate a resulting material, which may be referred to as a deposition material 510.

In some examples, the material vapour 210 interacts with the ionised gas of the plasma 620, such that the vapour flux of the material vapour 210 is modified. The resulting deposition material 510 may therefore have a modified vapour flux. For example, the vapour flux of the material vapour 210 produced by the induction crucible apparatus may not be substantially constant across the deposition zone 230 e.g. there may be regions of greater or lesser density of material vapour 210. By transmitting the material vapour 210 through the plasma 620, and thus interacting the material vapour 210 with the ionised gas in the plasma 620, the variations in the vapour flux of the material vapour 210 may be reduced.

In some examples, material vapour 210 interacts with the ionised gas of the plasma 620, such that the chemical properties of the material vapour 210 are modified. The resulting deposition material 510 may therefore have different chemical properties to the chemical properties of the material vapour 210.

For example, one or more reactions between the material vapour 210 and a gas (e.g. the ionised gas of the plasma and/or another gas in the deposition chamber) may generate a deposition material 510. Such a reaction process may be referred to as a reactive deposition process.

In some examples, a gas in the deposition chamber, which may be injected into the deposition chamber, may comprise one or more chemical elements and/or molecules that may chemically react with the material vapour 210 from the induction crucible apparatus. As a result, the material vapour 210 and the elements and/or molecules may chemically react, yielding one or more deposition materials 510. The deposition material 510 may then be used as part of a reactive deposition process. For example, the deposition material 510 may be deposited on a substrate.

In some examples, the material vapour 210 may be or comprise a precursor material, such that a reaction with the ionised gas of the plasma and/or another gas in the deposition chamber may generate a deposition material, for example for the production of an energy storage device.

For example, for the production of an energy storage device, the material vapour 210 may be or comprise a precursor material for a cathode layer of an energy storage device. Reactions with the precursor material may occur, generating a deposition material which is suitable for a cathode layer e.g. a deposition material suitable for storing lithium ions, such as lithium cobalt oxide, lithium iron phosphate or alkali metal polysulphide salts.

Additionally, or alternatively, the material vapour 210 may be or comprise a precursor material for an anode layer of an energy storage device. Reactions with the precursor material may occur, generating a deposition material which is suitable for an anode layer e.g. a deposition material comprising lithium metal, graphite, silicon or indium tin oxides.

Additionally, or alternatively, the material vapour 210 may be or comprise a precursor material for an electrolyte layer of an energy storage device. Reactions with the precursor material may occur, generating a deposition material which is suitable for an electrolyte layer e.g. a material which is ionically conductive, but which is also an electrical insulator, such as lithium phosphorous oxynitride (LiPON). For example, the material vapour 210 may be or comprise LiPO as a precursor material for the deposition of LiPON onto the substrate, for example, via reaction with nitrogen gas in the plasma and/or in the deposition chamber.

Controlling the properties of the plasma 620 may allow the properties of the deposition material 510 to be controlled. For example, controlling the properties of the ionised gas of the plasma 620 may allow the reaction between the material vapour 210 and the ionised gas of the plasma 620 to be controlled. As such, the properties of the resulting deposition material 510 may also be controlled.

For example, controlling the concentration of a gas in the plasma and/or the deposition zone 230 may be used to control the rate of reaction between the gas and the material vapour produced by the induction crucible apparatus and/or a crystal structure (e.g. crystallinity) of a crystalline deposition material deposition on a substrate. In one example, controlling the concentration of nitrogen gas in the plasma and/or the deposition zone 230 may control the rate of reaction between a LiPO material vapour and the nitrogen gas to produce a LiPON deposition material. The electrolyte material LiPON has a crystalline structure which forms a solid electrolyte layer. The crystalline structure may have a regular structure, with an ordered arrangement of atoms, which may be arranged as a two-dimensional or three-dimensional lattice. By controlling the concentration of nitrogen gas, the rate of production of the LiPON deposition material may be controlled. Furthermore, the crystalline structure of the LiPON deposition material may be controlled. In another example, controlling the concentration of oxygen gas in the plasma and/or the deposition zone 230 may control the rate of reaction between a lithium and/or cobalt (precursor) material vapour and the oxygen gas to generate a lithium cobalt oxide (LiCoO) deposition material. For example, the material vapour may be or comprise lithium and/or cobalt, for use as a precursor material, such that the precursor material participates in a chemical reaction that produces a deposition material. Upon heating of the precursor material by the induction crucible apparatus, a lithium and/or cobalt material vapour is produced. Interaction of the lithium and/or cobalt material vapour with the oxygen gas in the plasma and/or the deposition zone may generate a lithium cobalt oxide (LiCoO) deposition material. The ability to perform a reactive deposition process provides the possibility of generating a wide variety of deposition material for deposition on the substrate

FIG. 7 is a schematic diagram of a plasma generation system 700. The features of FIG. 7 which are similar to corresponding features of FIGS. 1 to 6 are labelled with the same reference numeral. Corresponding descriptions are to be taken to apply, unless otherwise stated.

The plasma generation system 700 in the example of FIG. 7 is similar to that of FIG. 6 but additionally comprises a gas supply system 701a, 701b, 701c configured to provide at least one gas 702a, 702b, 702c between an induction crucible apparatus (not shown) and a substrate support (not shown).

The gas supply system 701a, 701b, 701c in FIG. 7 comprises a first gas inlet 701a to provide a first gas 702a through the plasma 620. When the first gas inlet 701a is configured to provide a first gas 702a, the ionised gas of the plasma 620 may comprise an ionised form of the first gas 702a. As such, the material of the material vapour 210 may interact (and react) with the ionised first gas 702a of the plasma 610.

In some examples, the first gas inlet 701a may be located in the deposition system so that the first gas 702a is provided through the plasma 620 e.g. the first gas 702a is transmitted into the plasma 620. As such, the first gas 702a may be ionised in the plasma 620, generating an ionised form of the first gas 702a.

The gas supply system 701a, 701b, 701c may further comprise a second gas inlet 701b to provide a second gas 702b between the plasma 620 and the induction crucible apparatus. When the second gas inlet 701b is configured to provide a second gas 702b, at least part of the gas in the deposition zone 230 may comprise the second gas 702b. As such, the material of the material vapour 210 may interact (and react) with the second gas 702b.

In some examples, the second gas inlet 701b may be located in the deposition system so that the second gas 702b is provided above the induction crucible apparatus and beneath the plasma 620. In such a configuration, the material vapour 210, generated by the induction crucible apparatus and moving in a direction 220, will be first transmitted through the second gas 702b and then transmitted through the plasma 620. Transmission of the material vapour 210 through the second gas 702b may cause the material vapour 210 to interact with the second gas 702b. Furthermore, transmission of the material vapour 210 through the plasma 620 may cause the material vapour 210 to interact with the plasma 620. Such interactions may generate, at least in part, a deposition material 520. In some examples, not all of the material vapour 210 interacts with the second gas 702b and/or the plasma 620. As a result, the deposition material 520 may, at least in part, comprise the material vapour 210.

The gas supply system 701a, 701b, 701c may further comprise a third gas inlet 701c to provide a third gas 702c between the plasma 620 and the substrate support. When the third gas inlet 701c is configured to provide a third gas 702c, at least part of the gas in the deposition zone 230 may comprise the third gas 702b. As such, the material of the material vapour 210 and/or the material of the deposition material 510 may interact (and react) with the third gas 702c.

In some examples, the third gas inlet 701c may be located in the deposition system so that the third gas 702c is provided above the plasma 620 and beneath the substrate support. In such a configuration, the deposition material 520, generated by the interaction with the plasma 620, is transmitted through the third gas 702c. Transmission of the deposition material 520 through the third gas 702c may cause the deposition material 520 to interact with the third gas 702c. In some examples, not all of the deposition material 520 interacts with the plasma 620 and/or the third gas 702c. As such, the deposition material 520 may, at least in part, comprise the material vapour 210.

The deposition material 510 may comprise material of the material vapour 210 interacting with a gas 702a, 702b, 702c. Similarly, the deposition material 510 may comprise material of the material vapour 210 interacting with the plasma 620.

It is to be appreciated that the gas supply system 701a, 701b, 701c of FIG. 7 is merely an example. Other deposition systems may include any combination of the first, second and third gas inlets 701a, 701b, 701c. Furthermore, the first, second and third gases may be the same as or different from each other.

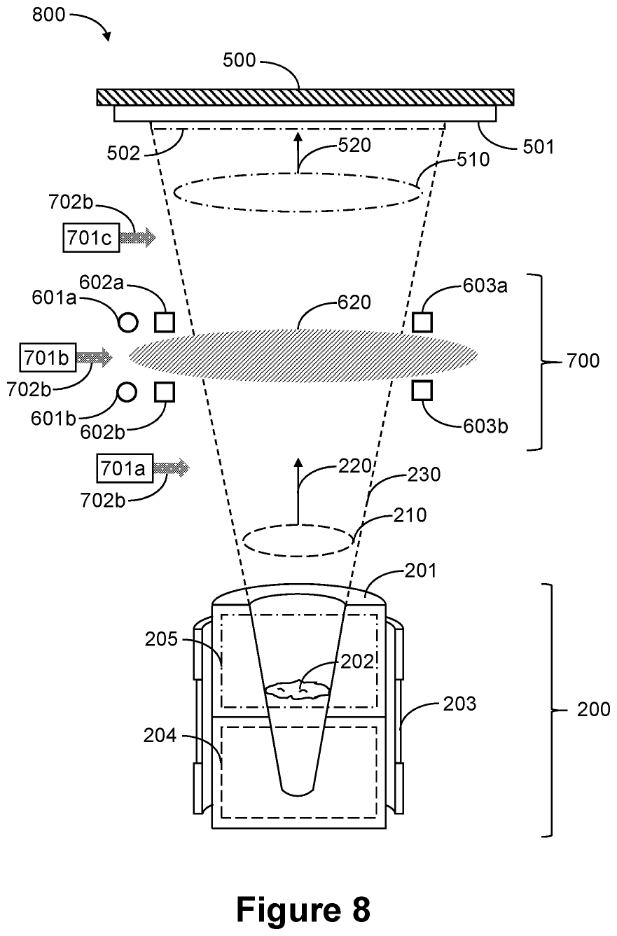

FIG. 8 is a schematic diagram of a deposition system 800. The features of FIG. 8 which are similar to corresponding features of FIGS. 1 to 7 are labelled with the same reference numeral. Corresponding descriptions are to be taken to apply, unless otherwise stated.

The deposition system 800 comprises an induction crucible apparatus 200 configured to produce a material vapour 210. The induction crucible apparatus 200 is configured to inductively heat a crucible 201 to generate two or more thermal zones 201a, 201b in the crucible 201. The deposition system 800 further comprises a substrate support 500 configured to support a substrate 501. Furthermore, the deposition system 800 comprises a plasma generation system 700 configured to generate a plasma 620 between the induction crucible apparatus 200 and the substrate support 500. Transmission of the material vapour 210 at least partly through the plasma 620 generates a deposition material 510 for deposition on the substrate 501.

An induction crucible apparatus may provide a high rate of production of the material vapour but may suffer from localised regions in the material vapour of higher or lower density, which may create a non-uniform deposition of a deposited material on a substrate. The use of a plasma, in the convention sputter deposition process, can break down the material vapour into a uniform structure, inject energy into the material vapour and provide gas for reactive deposition. However, sputter deposition processes but may suffer from a low rate of production of the material vapour.

In examples described herein, the combination of the induction crucible apparatus 200 and the plasma 620 may provide various improvements. By combining the induction crucible apparatus 200 with the plasma 620, a high rate of production of the material vapour can be combined with the ability to modify the material vapour 210 to have a uniform or homogeneous density. As a result, a high rate of deposition material 510 with a uniform density may be generated for deposition on the substrate 501. The high rate of production of the material vapour 210 may be achieved using a relatively lower energy for the deposition system 800, compared to electron-beam deposition or resistive heating of a crucible. As such, a lower energy is required to evaporate the material 202 in the crucible 201 to create a material vapour 210. Furthermore, use of the induction crucible apparatus 200 may allow for a high degree of control of the stoichiometry of the deposition material 510 due to the ability to control the evaporation (or vaporisation) rate of the material 202 in the crucible 201 to create the material vapour 210, compared to electron-beam deposition or plasma vapour deposition. The ability to control the evaporation rate of the material results from the ability to control the electric power applied to the one or more induction coils 203 of the induction crucible apparatus 200. Furthermore, a higher degree of control over the size and/or the shape of the material vapour 210 may be provided by configuring the shape of the crucible 201, in comparison to sputter deposition. Furthermore, interacting the material vapour 210 with the plasma 620 may cause the energy associated with the material vapour 210 to be retained or increased, in order to generate the deposition material 510. As such, the deposition material 510 may be deposited on the substrate with enough energy to form a deposited material with a high-energy crystalline structure. By generating a high-energy deposition material 510, the requirement to provide additional energy from an additional process step may be avoided. For example, the requirement of an annealing step in the deposition process may be avoided, as the interaction of the plasma 610 with the material vapour 210 may provide the required energy to generate the high-energy deposition material 510 needed to create a crystalline structure.

The induction crucible apparatus 200 may further comprise the crucible 201 and one or more induction coils 203 arranged around the crucible 201. Upon application of electric power to the one or more induction coils 203, a first thermal zone 204 is generated in at least a first portion of the crucible 201 and a second thermal zone 205 is generated in at least a second portion of the crucible 201. A first temperature of the first thermal zone 204 may be different from a second temperature of the second thermal zone 205.

The one or more induction coils 203 may comprise a first induction coil arranged around the first portion of the crucible and a second induction coil arranged around the second portion of the crucible. A first electric power may be applied to the first induction coil and a second electric power may be applied to the second induction coil. The second electric power may be different from the first electric power.

The first portion of the crucible may be located between a base of the crucible 201 and the second portion of the crucible 201. Upon application of electric power to the one or more induction coils 203, the first temperature of the first thermal zone 204 may meet or exceed a first temperature threshold for melting of the material to be heated by the induction crucible apparatus 200. Additionally, or alternatively, upon application of electric power to the one or more induction coils 203, the second temperature of the second thermal zone 205 may meet or exceed a second temperature threshold for vaporisation of the material to be heated by the induction crucible apparatus 200 in order to produce the material vapour 210.

The plasma source 610 may be configured to generate the plasma 620 between the induction crucible apparatus 200 and the substrate support 500 such that the plasma 620 is substantially absent from the crucible 201.

A gas supply system 701a, 701b, 701c may be configured to provide at least one gas 702a, 702b, 702c between the induction crucible apparatus 200 and the substrate support 500.

The gas supply system 701a, 701b, 701c may comprise a first gas inlet 701a to provide a first gas 702b though the plasma 620. The gas supply system 701a, 701b, 701c may further comprise a second gas inlet 701b to provide a second gas 702b between the plasma 620 and the induction crucible apparatus 200. The gas supply system 701a, 701b, 701c may further comprise a third gas inlet 701c to provide a third gas 702c between the plasma 620 and the substrate support 500.

The gas supply system 701a, 701b, 701c may be further configured to control a rate at which the at least one gas 702a, 702b, 702c (collectively referred to with the reference numeral 702) is provided between the induction crucible apparatus 200 and the substrate support 500. The gas may comprise nitrogen, argon, oxygen, ammonia, nitrogen oxide and/or helium.

A gas, which may be a first gas 702a, a second gas 702b and/or a third gas 702c, may be provided to the deposition chamber by the gas supply system 701a, 701b, 701c at a given rate. For example, the rate at which the gas is provided to the deposition chamber may be controlled by the gas supply system 701a, 701b, 701c.

In some examples, the gas may be provided at a first rate at a first time, in order to generate a first deposition material 510. Generation of the first deposition material 510 may be performed by transmitting the material vapour 210 at least partly through the gas 702 and/or the plasma 620 at the first time. The first deposition material 510 may have characteristics dependent on the first rate of the gas 702. The rate at which the gas 702 is provided to the system (e.g. the first rate) may determine the characteristics of the first deposition material 510. For example, when the rate at which the gas 702 is provided to the system is slow, there may be a low concentration of gas 702 in the deposition chamber. As a result, there may be a small probability of the material vapour 210 interacting and/or reacting with the gas 702. Therefore, the rate of production of the first deposition material 510 (generated from the interaction with the material vapour 210 and the gas 702a) may be low. The first deposition material 510 may be deposited on the substrate 501 to create a layer 502 of first deposited material. As a result, the layer 502 of first deposited material will have characteristics depended on the rate at which the gas 702 is provided to the system.

In some examples, the gas 702 may be provided at a second rate at a second time, in order to generate a second deposition material 510. The second rate may be different from the first rate and the second time may be different from the first time e.g. the second time may be later than the first time. Generation of the second deposition material 510 may be performed by transmitting the material vapour 210 at least partly though the gas 702 and/or the plasma 620 at the second time. The rate at which the gas 702 is provided to the system (e.g. the second rate) may determine the characteristics of the second deposition material 510. For example, when the rate at which the gas is provided to the system is fast (e.g. faster than the first rate), there may be a higher concentration of gas 702 in the deposition chamber. As a result, there may be a higher probability of the material vapour 210 interacting and/or reacting with the gas 702. Therefore, the rate of production of the deposition material 510 (generated form the interaction with the material vapour 210 and the gas 702) may be higher (e.g. higher than the production with the first rate). The second deposition material 510 may be deposited on the substrate 501 to create a layer 502 of second deposited material. As a result, the layer 502 of second deposited material will have characteristics which depend on the rate at which the gas 702 is provided to the system.

In further cases, the characteristics of the deposited material may depend on the relative proportion of at least two different gases provided in the deposition zone 230, e.g. by the first, second and/or third inlets 701a, 701b, 701c. It is to be appreciated that, in some cases, the deposition system may have more or fewer gas inlets than those of FIG. 8, which is merely an example.

In some examples, the layer 502 of deposited material (e.g. the first deposited material and/or the second deposited material) may be analysed to determine its characteristics. For example, the layer 502 of deposited material may be analysed by a spectroscopic technique, such as, but certainly not limited to x-ray diffraction, x-ray photoelectron spectroscopy, Raman spectroscopy, infrared spectroscopy and/or nuclear magnetic resonance spectroscopy. Performing spectroscopy on the layer 502 of the deposited material can provide spectroscopic data on the characteristics of the layer 502 e.g. the thickness or depth of the layer 502, the uniformity or homogeneity of the layer 502, the crystalline structure, the chemical composition and/or the electrical properties, such as ionic conductivity and activation energy. The spectroscopic data may be used as part of a feedback loop in order to maintain one or more characteristics of the layer 502 automatically, without the need for manual intervention.

For example, after analysis of the spectroscopic data for a layer 502 of the first deposition material, parameters of the deposition system (e.g. rate of production of the material vapour, electric power applied to the one or more induction coils, density of the plasma and/or rate of gas provided to the deposition system) may be modified in order to modify the properties of the layer 502 of the first deposition material. After modification, a second deposition material is deposited on the substrate to create a layer 502 of the second deposited material. As a result, the properties of the layer 502 of the second deposited material may be different from the properties of the layer 502 of the first deposition material. For example, the parameters of the deposition system may be modified in order to maintain substantially constant or consistent properties of the layer 502 of the deposited material as the deposition process is performed and the materials in the deposition system (e.g. material 202 in the crucible 201, gas 702 in the deposition chamber etc.) vary.

The properties of the deposition material (e.g. material properties, electrical properties and/or chemical properties) may be controlled by controlling a rate of production of the material vapour. For example, the thickness and/or the density of the deposition material deposited on the substrate may be higher when the material vapour is produced at a higher rate. In some examples, increasing the temperature of one or more of the thermal zones in the induction crucible may increase the rate of production of the material vapour.

In some examples, the electric power applied to the one or more induction coils 203 may be controlled by a feedback loop that is based, at least in part, on the temperature measurements by the temperature sensors for the first and/or second thermal zones 204, 205. As a result, the temperature of the first and/or second thermal zones 204, 205 can be controlled automatically. As such, a substantially constant material vapour 210, or a material vapour 210 with fewer vapour flux variations than existing systems, in the second thermal zone 205 may be achieved. As a result, one or more characteristics of the layer 502 (e.g. the thickness or density of the layer 502, the uniformity or homogeneity of the layer 502 and/or the chemical composition) may be controlled automatically.

The properties of the deposition material (e.g. material properties, electrical properties and/or chemical properties) may be controlled by controlling a density of the plasma. For example, the uniformity or homogeneity of the deposition material deposited on the substrate may be increased by increasing the density of the plasma. In some examples, generating a high-density plasma provides a greater probability of the material vapour interacting and reacting with the plasma, in order to produce a uniform or homogeneous deposition material.

In some examples, the density of the plasma 620 (e.g. controlled by the plasma source 610) may be controlled by a feedback loop that is based, at least in part, on the spectroscopic data for the layer 502 of the deposited material. As a result, one or more characteristics of the layer 502 (e.g. the thickness or density of the layer 502 and/or the uniformity or homogeneity of the layer 502) may be controlled automatically.

The properties of the deposition material (e.g. material properties, electrical properties and/or chemical properties) may be controlled by controlling the rate of gas provided to the deposition system. For example, the rate of production of a deposition material may be increased by providing a higher rate of gas, such that the material vapour has a greater probability of interacting with the gas (to produce the deposition material) in the deposition system.

In some examples, the rate at which the gas 702 is provided to the system (e.g. controlled by the gas supply system 701a, 701b, 701c) may be controlled by a feedback loop that is based, at least in part, on the spectroscopic data for the layer 502 of the deposited material. As a result, one or more characteristics of the layer 502 (e.g. the crystalline structure and/or the chemical composition) may be controlled automatically.

Depositing the deposition material on the substrate may comprise depositing the deposition material substantially homogeneously on the substrate. The deposition of the material on the substrate may be considered to be substantially homogeneous when the deposition on the substrate is approximately homogeneous. The deposition on the substrate may be considered to be approximately homogeneous when the thickness or depth of the deposited material on the substrate is approximately constant across the substrate. For example, the thickness of the deposited material on the substrate may be approximately constant within measurement tolerances or with a variation of within plus or minus 1, 5 or 10 percent of the thickness of the deposited material on the substrate.

Furthermore, depositing the deposition material on the substrate may comprise depositing the deposition material with a crystalline structure on the substrate. For example, the deposition process may be used to deposit an electrolyte layer on the substrate, such as LiPON. In some examples, the electrolyte material LiPON may be generated from the reaction of LiPO material vapour with nitrogen gas in the plasma and/or deposition chamber. As described above, controlling the rate at which the nitrogen gas is provided to the deposition chamber may be controlled by the gas supply system 701a, 701b, 701c. As a result, the characteristics of the crystalline structure of the LiPON deposition material may be controlled by the gas supply system 701a, 701b, 701c e.g. the rate of production of the LiPON deposition material or the structure of the LiPON deposition material itself.

The deposition system 800 may be configured to transmit the material vapour 210 at least partly through the plasma 620. Furthermore, the deposition system 800 may be configured to transmit the material vapour 210 at least partly through the gas 702 to interact material of the material vapour 210 with the at least one gas 702 and/or the plasma 620 to generate the deposition material 510.

The deposition system 800 may be arranged for use in manufacture of an energy storage device. For example, the deposition material 510 may comprise material for an electrode layer or an electrolyte layer of an energy storage device.

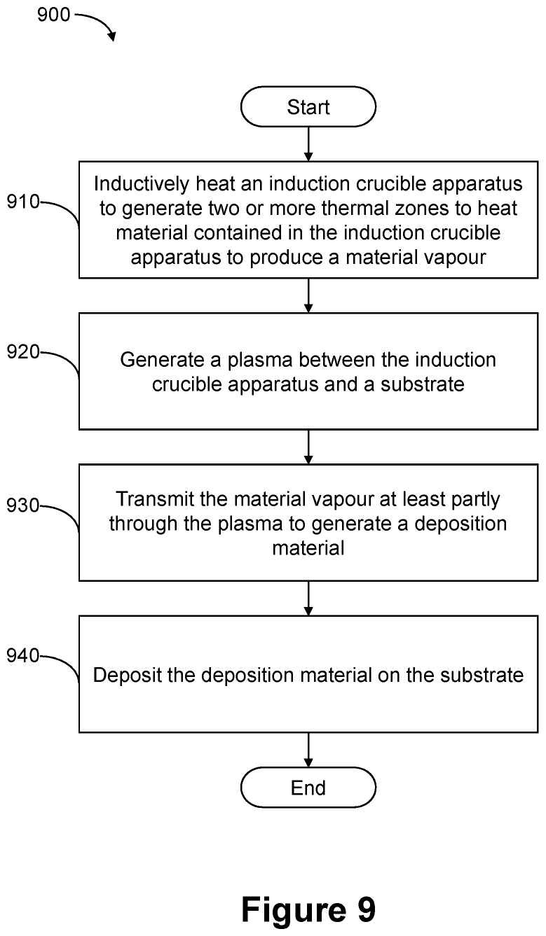

FIG. 9 is a flow diagram illustrating a method for depositing a deposition material on a substrate. The method may be implemented using the systems described above.

In block 910 of the flow diagram 900, an induction crucible apparatus is inductively heated to generate two or more thermal zones to heat material contained in the induction crucible apparatus to produce a material vapour.

In block 920 of the flow diagram 900, a plasma is generated between the induction crucible apparatus and a substrate.

In block 930 of the flow diagram 900, the material vapour is transmitted at least partly through the plasma to generate a deposition material.

In block 940 of the flow diagram 900, the deposition material is deposited on the substrate.

The above examples are to be understood as illustrative examples. Further examples are envisaged. It is to be understood that any feature described in relation to any one example may be used alone, or in combination with other features described, and may also be used in combination with one or more features of any other of the examples, or any combination of any other of the examples. Furthermore, equivalents and modifications not described above may also be employed without departing from the scope of the accompanying claims.

1. A deposition system comprising:
an induction crucible apparatus configured to produce a material vapour, wherein, in use, the induction crucible apparatus is configured to inductively heat a crucible to generate two or more thermal zones in the crucible;
a substrate support configured to support a substrate; and
a plasma source configured to generate a plasma between the induction crucible apparatus and the substrate support such that transmission of the material vapour at least partly through the plasma generates a deposition material for deposition on the substrate.

2. The deposition system of claim 1, wherein the induction crucible apparatus comprises:
the crucible; and
one or more induction coils arranged around the crucible such that, upon application of electric power to the one or more induction coils, a first thermal zone is generated in at least a first portion of the crucible and a second thermal zone is generated in at least a second portion of the crucible,
wherein a first temperature of the first thermal zone is different from a second temperature of the second thermal zone.

3. The deposition system of claim 2, wherein the one or more induction coils comprise:
a first induction coil arranged around the first portion of the crucible; and
a second induction coil arranged around the second portion of the crucible, such that a first electric power is applicable to the first induction coil and a second electric power, different from the first electric power, is applicable to the second induction coil.

4. The deposition system of claim 2, wherein the first portion of the crucible is located between a base of the crucible and the second portion of the crucible and, upon application of electric power to the one or more induction coils, at least one of:
the first temperature of the first thermal zone meets or exceeds a first temperature threshold for melting of the material to be heated by the induction crucible apparatus, in use; or
the second temperature of the second thermal zone meets or exceeds a second temperature threshold for vaporisation of the material to be heated by the induction crucible apparatus, in use, to produce the material vapour.

5. The deposition system of claim 1, wherein the plasma source is configured to generate the plasma between the induction crucible apparatus and the substrate support such that the plasma is substantially absent from the crucible.

6. The deposition system of claim 1, comprising a gas supply system configured to provide at least one gas between the induction crucible apparatus and the substrate support.

7. The deposition system of claim 6, wherein the gas supply system comprises at least one of:
a first gas inlet to provide a first gas though the plasma, in use;
a second gas inlet to provide a second gas between the plasma and the induction crucible apparatus, in use; or
a third gas inlet to provide a third gas between the plasma and the substrate support, in use.

8. The deposition system of claim 6, wherein the gas supply system is configured to control a rate at which the at least one gas is provided between the induction crucible apparatus and the substrate support.

9. The deposition system of claim 6, wherein the deposition system is configured to transmit the material vapour at least partly through the plasma and at least partly through the gas to interact material of the material vapour with the at least one gas and/or the plasma to generate the deposition material, in use.

10. The deposition system of claim 1, wherein the deposition system is arranged for use in manufacture of an energy storage device.

11. A method comprising:
inductively heating an induction crucible apparatus to generate two or more thermal zones to heat material contained in the induction crucible apparatus to produce a material vapour;
generating a plasma between the induction crucible apparatus and a substrate;
transmitting the material vapour at least partly through the plasma to generate a deposition material; and
depositing the deposition material on the substrate.

12. The method of claim 11, wherein inductively heating the induction crucible apparatus comprises:
applying electric power to one or more induction coils arranged around a crucible of the induction crucible apparatus to generate a first thermal zone in a first portion of the crucible and a second thermal zone in a second portion of the crucible,
wherein a first temperature of the first thermal zone is different from a second temperature of the second thermal zone.

13. The method of claim 12, wherein the first portion of the crucible is located between a base of the crucible and the second portion of the crucible and inductively heating the induction crucible apparatus further comprises configuring the first temperature and the second temperature to at least one of:
melt a first portion of the material in the first portion of the crucible; and
vaporise a second portion of the material in the second portion of the crucible to produce the material vapour.

14. The method of claim 11, wherein the plasma is substantially absent from the induction crucible apparatus.

15. The method of claim 11, comprising providing at least one gas between the induction crucible apparatus and the substrate.

16. The method of claim 15, wherein generating the deposition material comprises material of the material vapour interacting with the at least one gas and/or the plasma.

17. The method of claim 15, comprising providing a gas of the at least one gas:
at a first rate at a first time to generate the deposition material as a first deposition material at the first time, by transmission of the material vapour at least partly the plasma and at least partly through the gas; and
at a second rate, different from the first rate, at a second time different from the first time, to generate a second deposition material different from the first deposition material at the second time, by transmission of the material vapour at least partly the plasma and at least partly through the gas.

18. The method of claim 17, wherein the first deposition material has a different chemical composition than the second deposition material.

19. The method of claim 15, wherein the at least one gas comprises nitrogen, argon, oxygen, ammonia, nitrogen oxide and/or helium.

20. The method of claim 15, comprising controlling a rate of providing a gas of the at least one gas to control a crystallinity of the deposition material deposited on the substrate.

21. The method of claim 11, comprising controlling at least one of a rate of production of the material vapour or a density of the plasma to control a material property of the deposition material.

22. The method of claim 11, wherein depositing the deposition material on the substrate comprises depositing the deposition material substantially homogeneously on the substrate.

23. The method of claim 11, wherein depositing the deposition material on the substrate comprises depositing the deposition material with a crystalline structure on the substrate.

24. The method of claim 11, wherein the deposition material deposited on the substrate comprises material for an electrode layer or an electrolyte layer of an energy storage device.

25. (canceled)
